(19) United States
(12) Patent Application Publication
(10) Pub. No.: US 2021/0286859 A1
(43) Pub. Date: Sep. 16, 2021

(54) SYSTEM, METHOD AND COMPUTER READABLE MEDIUM FOR SENSITIVITY OF DYNAMICAL SYSTEMS TO INTERACTION NETWORK TOPOLOGY

(71) Applicant: University of Virginia Patent Foundation, Charlottesville, VA (US)

(72) Inventors: Stephen EUBANK, Charlottesville, VA (US); Srini VENKATRAMANAN, Charlottesville, VA (US); Madhurima NATH, Charlottesville, VA (US); Yihui REN, Charlottesville, VA (US)

(73) Assignee: University of Virginia Patent Foundation, Charlottesville, VA (US)

(21) Appl. No.: 17/185,476

(22) Filed: Feb. 25, 2021

Related U.S. Application Data
(60) Provisional application No. 62/982,529, filed on Feb. 27, 2020.

(51) Int. Cl. G06F 17/11; G06F 17/18; G06F 17/17

(52) U.S. Cl. CPC G06F 17/11; G06F 17/17; G06F 17/18

(57) ABSTRACT

Embodiments disclose a system for determining a sensitivity of a networked system. The system identifies a vertex (V) that represents a constituent and a state of the constituent, and an interaction (E) between at least two Vs. An interaction-dependent function provides a probability that, when a perturbation occurs, a V will be in a certain state given that it is currently in a determined state and its neighbors are currently in determined states. A network reliability is used to determine a probability that a V's state holds when a perturbation occurs. The system evaluates only a certain amount of terms in a Taylor series from a sample, and identifies interpolating polynomials between the Taylor series. A cost function optimizes a property of the networked system for a fixed cost. The system perturbs the networked system until reliability is zero to estimate a sensitivity of the networked system.

### CROSS-REFERENCE TO RELATED APPLICATIONS

This application is related to and claims the benefit of U.S. provisional application No. 62/982,529, filed on Feb. 27, 2020, the entire contents of which is incorporated herein by reference.

### STATEMENT REGARDING FEDERALLY SPONSORED RESEARCH OR DEVELOPMENT

This invention was made with government support under Grant Nos. GM070694, awarded by the National Institutes of Health; CNS-1011769, awarded by the National Science Foundation; and HDTRA1-11-D-0016-0001 and HDTRA1-11-1-0016, awarded by the Department of Defense. The government has certain rights in the invention.

### FIELD

Embodiments relate to systems and methods that assess sensitivity of dynamical systems by apply perturbative expansions from statistical physics to a stochastic satisfiability problem that ranks vertices or edges in a networked dynamical system according to their estimated Birnbaum importance for monotonic dynamical properties under arbitrary dynamics.

### BACKGROUND INFORMATION

Interactions among constituents of networked dynamical systems are constrained by an interaction network. System trajectories depend not only on dynamical parameters but also on the interaction network's topology. Exact analysis of the dependence is known to be computationally complex and is infeasible for systems with more than a few dozen constituents.

### SUMMARY

Embodiments relate to systems, methods, and/or a computer readable medium configured to assess the sensitivity of a networked system, and in particular a networked dynamical system. For instance, a machine can be configured to carry our embodiments of the method. In some embodiments, the method can be embodied as program language (e.g., instructions) stored on a computer readable medium (e.g., main memory). Any of the processors disclosed herein can operatively associated with the computer readable medium and execute embodiments of the method via the program language.

It is contemplated for the network to be a networked dynamical system (e.g., a complex system including many units coupled by specific, potentially changing, interaction topologies). These can include a communication system, a system of autonomous or semi-autonomous robots, a power system, biological systems, epidemiological models, etc. Networked systems comprise of elements. An element is a constituent and the interaction between the constituent of that element and a constituent of another element. A constituent is denoted as a vertex, V. An interaction is denoted as an edge, E. The V's and E's can be modeled by mathematical functions. For instance, if the networked system is an epidemiological model, the V's can be people and the E's can be their interactions with each other. If the networked system is a power system, the V's can be capacitors, transformers, etc. and the E's can be which capacitor is taken on or off line. If the networked system is a communication system, the V's can be radios and the E's can be whether the radio is transmitting in a noisy environment.

Sensitivity of a networked system is an evaluation of the likelihood a critical path will change during a perturbation of the networked system. Thus, the sensitivity is an assessment of the probability a state will change due to a perturbation. The state can be the state of the networked system as a whole and/or the state of one or more V's in the networked system. The perturbation is a change to a V and/or an E. For instance, sensitivity can be an assessment of the likelihood a person will go from susceptible to infectious (e.g., a change in state) if social distance guidelines are changed, or the likelihood transmission will improve (e.g., a change in state) if a radio is upgraded. Inputs about the state of a V can be obtained by sensors, empirical epidemiological data, observations of the networked system, etc.

The sensitivity of a networked system can provide state distribution information (What is the probability that a certain number of Vs is in a particular state or will change due a particular perturbation?) and vulnerability information (What is the probability that a particular V is in a particular state or will change due to a particular perturbation?). Thus, sensitivity can provide community/structure (what are the state of Vs and how they relate to each other) of the system.

Every interaction can occur with its own conditional probability, w, which may be a complicated function of dynamical parameters, \vec{x}. With this, the dynamic of a networked dynamical system can be modeled. A set of dynamical parameters \vec{x} and an interaction-dependent function \vec{ω} (\vec{x}) that gives the transition probability for each interaction as a function of the dynamical parameters are considered. Usually, dim(\vec{x})<<dim \vec{ω} (\vec{x}), and the local functions are written as ω_{i,s′}(\vec{x}; s, s₁, . . . , s_{dt}). This provides a set of vertex-specific functions indexed by i and s′ that give the probability that vertex i will be in state s′ on the next time step given that it is currently in state s and its dᵢ neighbors in a dependency graph are currently in states s₁, . . . , s_{d}. Each local function gives the probability of a possible outcome of an interaction.

A sensitivity analysis can be viewed as a response surface or a network topology for the networked system. The methods disclosed herein use Taylor series approximations representative of the sensitivity of dynamical phenomena to individual interaction probabilities at the values w=0 (weak coupling) and w=1 (strong coupling).

Embodiments disclosed herein introduce the strong- and weak-coupling approximations of statistical physics to find approximate solutions to an underlying problem known as stochastic satisfiability in computer science and Moore-Shannon reliability in engineering. This approach is applicable to a wide range of networked dynamical systems. The resulting sensitivity analysis can be used, for example, to detect community structure, to prioritize network constituents for hardening against attack, to understand the risk of cascading failures in infrastructure networks, etc.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Other features and advantages of the present disclosure will become more apparent upon reading the following detailed description in conjunction with the accompanying drawings, wherein like elements are designated by like numerals, and wherein:

FIG. 1 shows Birnbaum importance in the N(m, a, b) networks. (Left) Estimated crossover points compared to the exact value for 48 toy networks as S, the number of samples, and D, the depth of expansion, are varied. (Right) Distribution of logarithms of the estimated Birnbaum importance for all 40, 109 edges in the PLP network under SIR dynamics with transmissibility x=0.075.

FIG. 2 shows GC size vs. vertices/edges removed from PLP. Fraction of the 5000 vertices contained in the giant component of PLP as a function of fraction of vertices (left panel) or edges (right panel) is removed. The horizontal line represents the goal of the methods that use Birnbaum importance. Curves for BIVV, BIEE, and CIVV are barely distinguishable in the right panel.

FIG. 3 shows probability of large clusters in PLP vs. vertices edges removed. The probability that there are more than 200 vertices in the largest connected cluster (LCC) of an ER-0.075 subgraph of the PLP network after removing top-ranked vertices or edges, as a function of fraction of vertices (left) or edges (right) removed.

FIG. 4 shows R₂₀₀ in PLP vs. x. R₂₀₀, the probability that there are more than 200 vertices in the LCC of an ER-x subgraph of PLP (after removing top-ranked vertices or edges), as a function of the transmissibility x. The top 100 (left) or 300 (right) vertices, ranked according to the indicated method, are removed. The curves for BIVV, CIVV, and DEGV are indistinguishable on the left. The vertical arrow at transmissibility 0.075 indicates where the B-based ranking was chosen to provide an approximate optimum reduction in reliability. This value is used for all the estimates in FIG. 3.

FIG. 5 shows Birnbaum importance vs. x. The Birnbaum importance, i.e., reduction in R₂₀₀, of the indicated sets in the PLP network. The curves for CIVV and DEGV are indistinguishable.

FIG. 6 represents a networked dynamical system as a hypergraph. Two hyperedges representing the possible interactions between a susceptible vertex (v₁) and an infectious vertex (v₂) under networked SIR dynamics. Solid curves connect the vertices in a hyper-vertex; dashed arrows connect the source and destination hyper-vertices in an interaction hyper-edge. The source hyper-vertex {v_{1.S}, v_{2.I}} in blue is the same for both interactions, and in both the red and the green interactions, the state of vertex two changes to “Removed”. The red hyper-edge, ({v_{1.S}, v_{2.I}}; {v_{1.I, v}_{2.R}}), represents an interaction that infects v₁ with probability w₁≡ω_{1.I}(\vec{x}; S, I)=x; the green, ({v_{1.S}, v_{2.I}}; {v_{1.S}, v_{2.R}}), one that fails to infect v₁ with probability 1−ω_{I}≡ω_{1.S}(\vec{x}; S, I)=1−x.

FIG. 7 shows a distinguishing occurrence from completion of an interaction. Four possible sets of interactions on a collapsed interaction network for SIR dynamics that include (indicated by solid lines) 1→2 and do not include (indicated by dashed lines) 2→3 or 2→4.

FIG. 8 shows the N(m, a, b) networks and their duals. (Left) A 3-parameter family of interaction networks, N(m, a, b). The dashed lines indicate sequences of either a-3 or b-3 vertices, which are not shown. The dotted line indicates m−2 sequences of a vertices, which are not shown. For b≤a, the B edges constitute the shortest path from S to T. There are m other paths, which all share the edge A₀. By symmetry, it is clear that Birnbaum importance for ST-reliability partitions the edges into three equivalence classes, indicated by colors: {A₀}, {B₁, . . . , B_{b}}, and {A₁₁, . . . , Aₘₐ}. (Right) Duals of the networks in the left panel under [symbol] _{ST}:

FIG. 9 shows a strut/cut separatrix. A lattice of all subgraphs for a graph with four edges. The top line of each label shows which edges are included in the subgraph; the bottom row, which edges are not included. Subgraphs in the same row of the lattice include the same number of edges. Lines between subgraphs indicate that they differ by a single edge. Subgraphs that are struts under a notional property [symbol] are shown as squares; cuts are shown as circles. Those that are minimal, i.e., cruxes, have white backgrounds. If [symbol] is monotonic, a separatrix such as that shown by the thick solid line separates cuts from struts. Subgraphs joined by darker lines are on opposite sides of the separatrix. Any path from the top to bottom of the lattice—such as the one indicated by a dashed line—contains exactly one darker line, i.e., it crosses the separatrix exactly once.

FIG. 10 shows a two-point Taylor interpolation. The function ƒ(x)=x³+x[1−(1−x³)⁶](1−x³), which is the ST-reliability for N (6, 3, 3), is the smooth, monotonic curve from (0,0) to (1,1) shown in black in both panels. (Left) Six Taylor series approximations to ƒ(x) are shown: three at x=0 including terms up to order x⁶, x⁹, or x¹⁰; and three at x=1 including terms up to order (1−x)², (1−x)³, or (1−x)⁸. These are the Taylor coefficients that are correctly given by combinations of up to one, two, or three minimal struts or cuts, respectively. (Right) Bounds and a Bezier interpolation constructed from the Taylor series of ƒ(x) with the terms correctly given by combinations of up to two minimal struts or cuts.

FIG. 11 shows relative Birnbaum importance. The effect on reliability of removing either of two edges a or b from an interaction network's edge set, E. Because r_{b}−rₐ may be many orders of magnitude less than r₊, direct comparison is not straightforward.

FIG. 12 shows a degree distributions of test networks. The degree distribution (left) and cumulative distribution (right, starting from the highest degree) of the PLP (top) and SF or SF+PLP (bottom) networks. Note the logarithmic scales for the scale free networks.

FIG. 13 shows a distribution of Birnbaum importance for test networks. Distribution of logarithms base 10 of the estimated Birnbaum importance for all 9,996 edges in the SF (left) and SF+PLP (right) networks under SIR dynamics with transmissibility x=0.19. The effect of community structure is evident in the distribution for SF+PLP.

FIG. 14 shows GC size vs. vertices/edges removed. Fraction of the 5000 vertices contained in the giant component as a function of fraction of vertices (left panel) or edges (right panel) removed from the SF network (top) or SF+PLP network (bottom). The horizontal line represents the point at which it is impossible to form a cluster of size 200 vertices, i.e., the goal of the BI methods. The corresponding figure for the PLP network appears in the main text as FIG. 2.

FIG. 15 shows the probability of large clusters in PLP vs. vertices/edges removed. The probability that the largest ER-0.075 cluster of PLP contains more than 400 vertices (top) or 800 vertices (bottom) as a function of fraction of vertices (left) or edges (right) removed. A similar plot for size threshold of 200 vertices appears in the main text as FIG. 3.

FIG. 16 shows the probability of large clusters in SF vs. vertices/edges removed. The probability that the largest ER-0.19 cluster of SF contains more than 200 vertices (top) or 400 vertices (bottom) as a function of fraction of vertices (left) or edges (right) removed. All of the RANV samples in this range of vertices removed contained more than 400 vertices. The curves for DEG, BIVV, and CIVV are barely distinguishable in these plots.

FIG. 17 shows the probability of large clusters in SF+PLP vs. vertices/edges removed. The probability that the largest ER-0.19 cluster of SF+PLP contains more than 200 vertices as a function of fraction of vertices (left) or edges (right) removed. The curves for DEG and CIVV are indistinguishable in these plots and all of the RANV samples contained more than 200 vertices.

FIG. 18 shows R₂₀₀ vs. x. R₂₀₀, the probability that the largest ER-x cluster contains more than 200 vertices after removing the top 10 (top left) or 100 vertices (top right) of SF or the top 1 (bottom left) or 10 vertices (bottom right) of SF+PLP, or the number of edges removed in each case by the CIVV method. The vertical arrows indicates the value for which the BI methods are optimized, which is the value used for all the estimates in FIGS. 14 and 15. The corresponding results for PLP are shown in FIG. 4 of the main text.

FIG. 19 shows Birnbaum importance vs. x. The Birnbaum importance, i.e., reduction in R₂₀₀), of the indicated sets for SF (top) or (bottom) SF+PLP (bottom). Curves for CIVV, DEGV, and BIVV are indistinguishable in several of the figures at this scale.

FIG. 20 shows R_{LCC200} vs. resilience. R_{LCC200} as a function of the resilience control parameter suggested in Gao, et al. (36) as vertices or edges are removed in the order specified by the indicated rankings.

FIG. 21 shows cluster decompositions of SF. (top row) SF network or (bottom row) the (left to right) 3636, 3852, 3816, and 4844 vertices with degree greater than zero in the CIVV, BIVV, BIEV, and BIEE LCC₂₀₀ cuts. In both rows, the vertices are arranged according to the corresponding clustering and colored according to degree in the SF network.

FIG. 22 shows a cluster decompositions of SF+PLP. (top row) SF+PLP network or (bottom row) the (left to right) 3449, 4079, 4105, and 4978 vertices with degree greater than zero in the CIVV, BIVV, BIEV, and BIEE LCC₂₀₀ cuts. In both rows, the vertices are arranged according to the corresponding clustering and colored according to degree in the SF+PLP network.

FIG. 23 shows cluster decompositions of PLP. (top row) PLP network or (bottom row) the (left to right) 1666, 1652, 1631 and 5000 vertices with degree greater than zero in the CIVV, BIVV, BIEV, and BIEE LCC₂₀₀ cuts. In both rows, the vertices are arranged according to the corresponding clustering and colored according to the planted clusters.

FIG. 24 shows quality of BIEE ranking for PLP. Fraction of edges removed by the BIEE approach that are among the inter-community edges for the PLP network, as a function of number of edges removed. The dashed curve indicates what would be expected at each step if the edges were chosen randomly from those that remain.

FIG. 25 is a block diagram illustrating an example of a machine upon which one or more aspects of embodiments of the present invention can be implemented.

FIG. 26 shows an example network of radios and communication channels. Edges with the same contribution to the satisfiability, as evident by symmetry, are colored the same.

FIG. 27 is a plot showing approximate solution with bounded, controllable error for an exemplar network.

FIG. 28 shows a comparison of exact and approximate solutions. Notice that the exact solution switches sign near x=0.618 and that neither Taylor series by itself can capture the crossover point well.

### DETAILED DESCRIPTION

A networked dynamical system can be described by a graph G(V,E) in which vertices in a set V represent system constituents, which may be in any of a finite number of states, and edges in a set E represent interactions. Every interaction can occur with its own conditional probability, w, which may be a complicated function of dynamical parameters, \vec{x}. Disclosed herein is Taylor series approximations developed for the sensitivity of dynamical phenomena to individual interaction probabilities at the values w=0 (weak coupling) and w=1 (strong coupling).

A canonical example of networked dynamics is networked SIR, a discrete time dynamical system that models the stochastic spread of something, e.g., information or disease, across an interaction network. Under networked SIR, pairwise interactions have the semantics of transmission: vertex i in the infectious state (“I”) transmits something independently to each of its network neighbors j in the susceptible (“S”) state with probability wᵢⱼ before transitioning to the removed (“R”) state. Any susceptible vertex that receives a transmission becomes infectious.

A system configuration specifies the states of all the vertices. An initial configuration for SIR specifies which vertices are infectious; all others are assumed to be susceptible. SIR dynamics are transient, reaching one of 2^{|V|} fixed configurations in at most |V| time steps. They are equivalent to random edge failure, or bond percolation (1).

The essential questions about networked dynamical systems are:
1. state distribution: What is the probability that a certain number of vertices is in a particular state?
2. vulnerability: What is the probability that vertex i is in a particular state?

These questions can be posed in terms of binary properties [symbol] of configurations. Moreover, the properties are monotonic: adding an interaction to G can only change the answer monotonically. The methods described here are appropriate for any monotonic property [symbol] .

Sensitivity analysis describes the response surface, i.e., the change in an observable when the system is perturbed. Often a tangent plane to the surface, defined by first-order partial derivatives of the observable, is sufficient description. For example, partial derivatives of a statistical physics partition function with respect to dynamical parameters connect macroscopic thermodynamic properties of a system such as heat capacity to microscopic dynamical quantities such as interaction strengths.

Network topology seems at first to be an inherently discrete “parameter”—an edge is either present or not—but interactions are associated with a continuous weight, their conditional probabilities. Hence, derivatives of an observable can be considered with respect to the conditional probabilities associated with interactions.

The disclosed methods involve a sensitivity analysis for edge-targeted perturbations, in which a specific set of interaction probabilities are perturbed while others are held constant. Vertex-targeted perturbations can be viewed as a special case of edge-targeted perturbation in which the probabilities of all interactions involving one or more specific vertices are perturbed. Both edge- and vertex-targeted perturbations are important. For example, in epidemiological models, they might represent social distancing and immunization, respectively.

Sensitivity analysis is often used to prioritize changes to a network, e.g., targeting, hardening, or upgrading. In these applications, the changes typically have a cost and the goal is to find a set of changes that optimally improves some property for a fixed budget. The solution depends not only on the dynamics and the property, but also on the cost function. Here, costs that are homogenous on either edges or vertices are considered. That is, the cost of removing a vertex is either fixed or proportional to its degree.

The methods described here are not heuristics, but interpolations between perturbative approximations—essentially Taylor series in interaction probabilities about two points. The interpolation is designed to match all the known Taylor series coefficients at both points, while obeying positivity and unitarity constraints. The approximation is two-fold: 1) sample S crucial structures from an enormous set and 2) evaluate only O(S^{D}) of the possible 2^{E} terms in the Taylor series, for D<<E. The nature of this approximation is unusual: it is possible to construct an interaction network whose sensitivity matches the estimate using the samples from step (1); or, taking the sampled Taylor coefficients to be exact, tight bounds for the truncation error in (2) can be developed.

Perturbative methods from statistical physics are applied to satisfiability problems to approximate the sensitivity of monotonic properties of arbitrary stochastic dynamical systems to arbitrary perturbations of network structure for interaction networks that are weighted, directed, vertex- and edge-labeled, asymmetric hypergraphs. The trade-off between approximation error and time complexity can be controlled by adjusting the sample size S and the expansion order D. Conventional techniques do not solve—or even to formulate—this problem at this level of generality. Related work includes:
Some have proposed heuristics for ranking constituents according to an implicit deterministic dynamics (2-5). Others have analyzed specific dynamical phenomena (6-8) or proposed general measures of centrality (9) that may be related to the sensitivity of some phenomena to network structure. A recent example of these is Morone and Makse's Collective Influence (CIVV) algorithm, which ranks vertices according to their influence on the size of the giant component in a deterministic interaction network. Removing vertices in the order specified by CIVV appears to minimize the size of the giant component in the remaining graph at each step. However, the size of the giant component only bounds certain dynamical properties. Furthermore, the CIVV method does not address stochastic systems or dependence on dynamics. Here, the performance of approximate rankings are compared with those determined by CIVV.
Community detection algorithms find cuts in the graph that maximize modularity (10). These cuts can provide insight into dynamical properties, but also ignore dynamics. Here, the performance of the disclosed approach is evaluated on a difficult community detection problem with a known solution.
There is an extensive literature on satisfiability, but much of it focuses on finding or counting solutions. Here the contribution a single variable makes to the probability a logical statement is true is considered.
Perturbative expansions, although widely used in statistical physics, are rarely applied to dynamics on irregular networks. Moreover, the use of Bezier polynomials to construct a principled interpolation between strong and weak-coupling expansions is novel (11). The methods disclosed herein are also applicable to more traditional statistical physics problems such as the Ising model on a 2- and 3-d lattice (12, 13).
The inventors have suggested (14-46) deriving sensitivity from Monte-Carlo estimates of Moore-Shannon network reliability, but this turned out to be impractical for large networks because the sensitivity to any individual constituent or interaction is tiny, e.g. e^{-E}.

As will be discussed in more detail later, this disclosure contains formal definitions, more detailed explanations for general cases, additional results that provide insight into how well the methods perform, and closed form solutions on a parameterized family of toy networks.

Methods

A stochastic dynamical system is completely specified by the probability it is in any configuration at any instant t, M(t). The dynamics determine M(t) given the values of a set of dynamical parameters, \vec{x} and an initial condition M₀. The dynamics can be expressed in extensional form in terms of interaction probabilities \vec{w}, which are functions of \vec{x}. Hence, this disclosure uses the terms “dynamics” and \vec{w} interchangeably.

A phenomenon of interest is represented as a binary property [symbol] of the system's configurations. For example, [symbol] may be true for all configurations in which more than a certain fraction of the vertices are in a certain state. Any configuration that exhibits property [symbol] is referred to herein as a [symbol] -configuration. Any set of interactions that leads to a [symbol] -configuration is referred to herein as a strut; any set that does not is referred to as a cut.

The Moore-Shannon network reliability (17), R_{G,} [symbol] (\vec{w}), is the probability that [symbol] holds under the dynamics \vec{w}, for a particular interaction network G given the initial condition. In other words, the reliability is the expectation value of [symbol] with respect to M or the total probability of configurations with property [symbol] . If the set of all configurations are partitioned into Q equi-probable equivalence classes, then the reliability can be written as a sum over equivalence classes

$${R}_{𝒢 , 𝒫} ( {w}^{->} ) ≡ {\sum }_{j = 1}^{Q} {n}_{𝒫} ( j ) {p}_{j} , \qquad ( 1 )$$

where pⱼ is the probability of any configuration in the j-th equivalence class and n [symbol] (j) is the number of configurations in the j-th equivalence class that arm [symbol] -configurations. In the language of statistical physics, n [symbol] (j) is a density of states function and R is a partition function. It is well known that evaluating the Moore-Shannon network reliability is NP-hard (18).

A monotonic system is one for which

[symbol]

(\vec{ω})≥ [symbol] (ω), (2)

∀g₁,g₂∈G. A monotonic system admits the notion of minimal struts and cuts. A strut (respectively, cut) is minimal if it has no proper subset that is a strut (respectively, cut). Reliability is completely determined by the set of minimal struts or cuts (16, 19, 20). For this reason, they are referred to as cruxes, which may either be minimal struts (s-cruxes) or minimal cuts (c-cruxes). Although many important properties are monotonic under bond percolation, not all are, e.g., the Girvan-Newman modularity of a network (10), often used as a metric in community detection.

The probability that a dynamical system reaches a [symbol] -configuration is given by the probability that all the interactions in at least one s-crux occur. This condition can be written naturally as a logical statement in disjunctive normal form (DNF) in terms of a set of basic events e representing the occurrence of particular interactions. Questions related to which assignments of truth values to the basic events render a logical statement true are called satisfiability (SAT) problems, or stochastic SAT when the basic events are probabilistic. For monotonic [symbol] , the SAT problem is also monotonic, i.e., every event enters only in the positive sense. It is far beyond the scope of this disclosure to review the extensive literature on SAT, but useful entry points are (21, 22). When developing the methods disclosed herein, a goal was to estimate the contribution of any single basic event eᵢ to the overall probability a logical statement is true.

Individual interactions are by definition statistically independent. Hence, the probability of the conjunction of basic events represented by a crux is simply the product of their individual probabilities. However, the probability of a disjunction of cruxes is more difficult to compute, because there are many combinations of basic events that can make it true. The well-known Inclusion-Exclusion expansion, based on the principle of unitarity, i.e., that p(A∨B) p(A)+p(B)−p(A∧B), can be used to transform the original SAT problem in DNF form to a finite, but large, alternating series that involves only conjunctions of basic events. The Inclusion-Exclusion expansion for s-cruxes produces a Taylor series for the reliability around the point \vec{w}=0. Truncating the series at terms of order p^{k} results in the k-th order weak-coupling expansion of statistical physics.

Similarly, when the basic events ēᵢ are interpreted as the event that interaction i does not occur, the Inclusion-Exclusion expansion for c-cruxes produces a Taylor series for 1−R(\vec{w}), the overall probability [symbol] that does not hold, about the point \vec{w}=1. This series is the strong-coupling expansion of statistical physics.

This duality between struts and cuts underlies the well-known MinCut-MaxFlow property (18, 23). Here, it is used to primarily change the final step in approximation from extrapolating a single Taylor series to interpolating between two Taylor series. It is also used to define a duality transformation for interaction networks that interchanges s-cruxes and c-cruxes.

Using Moore and Shannon's insight that network reliability is a finite-degree polynomial naturally represented in a basis of Bernstein polynomials (24, 25), a novel scheme for interpolating between the two expansions that optimally makes use of all the information contained in each and generates tight bounds on the approximation error is disclosed.

The Birnbaum importance B of any set g⊆G of network elements (vertices and/or edges) is defined as the change in network reliability when those elements are removed from the interaction network (26, 27), i.e.,

[symbol]

(g,\vec{ω})≡ [symbol] (\vec{ω})− [symbol] (\vec{ω}). (3)

Sensitivity \vec{S} is defined as a differential version of Birnbaum importance:

$${𝒮}_{i} ( 𝒢 , 𝒫 , {x}^{->} ) ≡ \frac{\partial {R}_{𝒢 , 𝒫} ( {w}^{->} )}{\partial {w}_{i}} {\vert}_{{w}^{->} = {w}^{->} ( {x}^{->} )} . \qquad ( 4 )$$

Individual elements in a typical large network do not contribute much to the reliability. Hence, approximating B requires distinguishing small differences. Although Monte Carlo estimation for the reliability itself is possible (14, 28), detecting small differences requires enormous sample sizes. A better approach is to estimate the difference in B for two sets g₁, g₂ by sampling a set of cruxes and determining which ones are still cruxes after removing g₁ or g₂. The relationships between these two sets determine the relative importance of g₁ and g₂.

An important use for sensitivity analysis is optimal targeting under resource constraints. Here the goal is to maximize a set function, the ratio of B to cost, over all feasible sets. When a set function is monotonic and submodular, a greedy algorithm that chooses the most important element on each step provides an optimal approximation, achieving a result within (1−1/e) of the optimum (8, 29). Unfortunately, B is not a submodular function of edges, as shown by a simple counter-example later in this disclosure. However, it is a submodular function of cruxes. This does not violate proven limits on SAT approximation difficulty because there can be exponentially more cruxes than edges.

Results

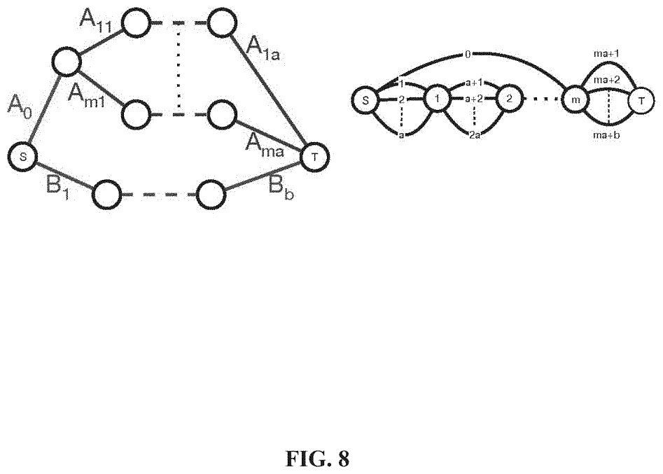

Homogenous SIR dynamics on four networks G is considered: a three-parameter family of toy networks N(m, a, b) and their duals, shown in FIG. 8; a scale-free (SF) network with 5000 vertices; a planted l-partition (PLP) network with 25 planted communities of 200 vertices each; and a scale-free planted l-partition (SF+PLP) network with the same partition structure as PLP and the same degree distribution as SF. Details of the networks and the rationale for choosing them are discussed in detail later.

Two properties [symbol] are considered:
1. The property [symbol] _{ST} is true for configurations in which a perturbation to the state of vertex S, e.g., infection, eventually reaches vertex T. This is equivalent to requiring that G contains a path from S to T. R_{ST} is often called “two-terminal” reliability; it is the two-point propagator of statistical physics.
2. The property [symbol] _{LCC200} is true for configurations in which a perturbation to the state of some vertex can reach at least 200 other vertices. This is equivalent to requiring that G contains a connected component with at least 201 vertices. [symbol] _{LCC200} was chosen for its ability, in principle, to identify the partitions of size 200 in PLP and SF+PLP.

For homogenous SIR dynamics with transmissibility x, the reliabilities associated with these properties can be computed using Erdös-Rényl random subgraphs of G, created by selecting each edge with probability x (“ER-x”). The usual convention of calling connected components in ER-x subgraphs clusters to distinguish them from the connected components of G itself is adopted. In particular, the largest connected (or giant) component in G is denoted by GC and the largest cluster in an ER-x subgraph of G is denoted by LCC-x.

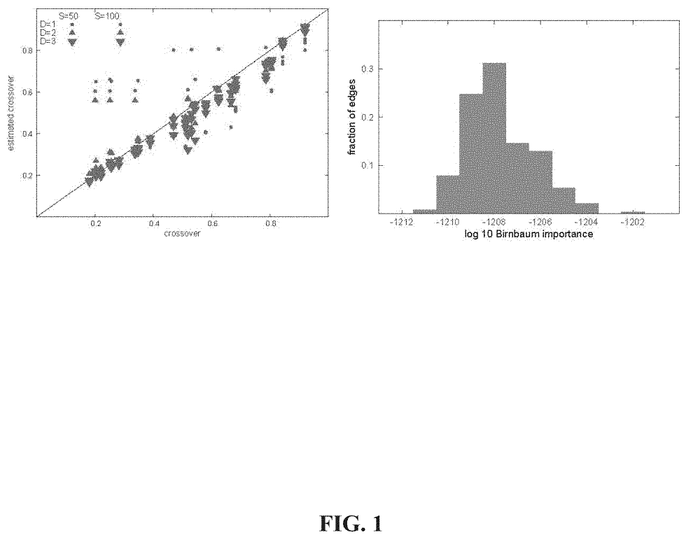

There are three equivalence classes of edges induced by Birnbaum importance in N (m, a, b). The importance of the two most important classes crosses over as transmissibility varies. Estimating the crossover transmissibility x_{c} is astringent test of the disclosed methods. The estimated x_{c} is compared to its exact value for several choices of sample size S and depth of expansion D for a range of m, a, and b in the left panel of FIG. 1. The estimated value converges rapidly to the exact value as S and D increase.

The right panel of FIG. 1 displays the distribution of estimated sensitivities for edges in the PLP network. Although sensitivity varies over 10 orders of magnitude, it is so small that direct Monte-Carlo estimation for a single edge would require on the order of 10¹²⁰⁰ samples.

It is not easy to find examples of networks for which the sensitivities are known. Instead, a related test, ranking, is considered. Elements are ranked by sensitivity and the process continues iteratively removing one with the highest importance/cost ratio, where cost is uniform across either vertices (BIVV) or edges (BIEV). By iterating until the reliability is reduced to zero, an approximately minimum-cost cut is found. To further demonstrate the method's flexibility, both edges (BIEE) and vertices are ranked. These ranking schemes are compared to ranking vertices by degree (DEGV), at random (RANV), or by collective influence (CIVV), and to ranking edges at random (RANE).

An element's rank may depend on 5. Hence, the reduction in reliability achieved by removing high-ranking elements is only expected to be optimal at a particular x. In these examples transmissibility x=0.075 is used for the PLP network and x=0.19 for the SF and SF+PLP networks, which are in transition regions for the corresponding network. Nonetheless, it is interesting to evaluate the reduction in reliability across the whole domain of \vec{x}.

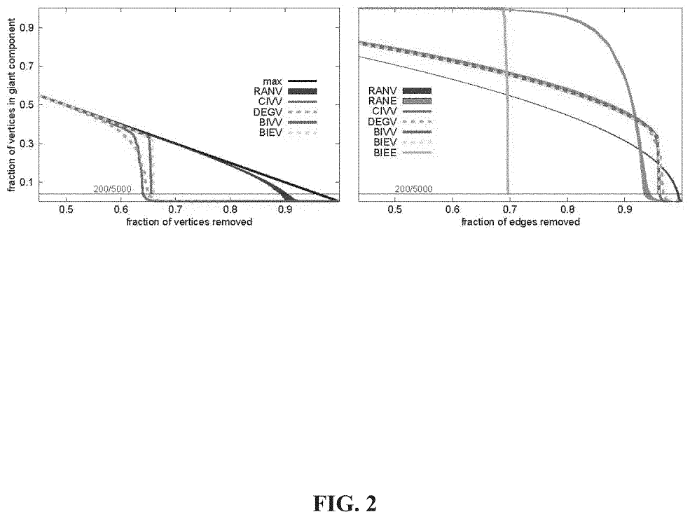

GC size is not trivially related to [symbol] _{LCC200}. For a fixed cost, the optimal reduction in GC size is not necessarily achieved by removing the same set of network elements as the optimal reduction in the corresponding reliability R₂₀₀. Nonetheless, following Morone & Makse, the reduction in GC size is exhibited as a function of vertices removed in FIG. 2 and compared to CIVV. As shown in the left panel, the CIVV algorithm outperforms other vertex-ranking methods at this task on PLP, although not on SF or SF+PLP (discussed later). The difference is every case is small but noticeable compared to the improvement over random ranking. However, it is no surprise that a surgical approach that removes individual edges instead of all edges connected to a particular vertex (BIEE) performs much better, as shown in the right panel of FIG. 2, where the x-axis shows the fraction of edges removed. Note also that, as a function of edges removed, both BIVV and BIEV slightly out-perform CIVV.

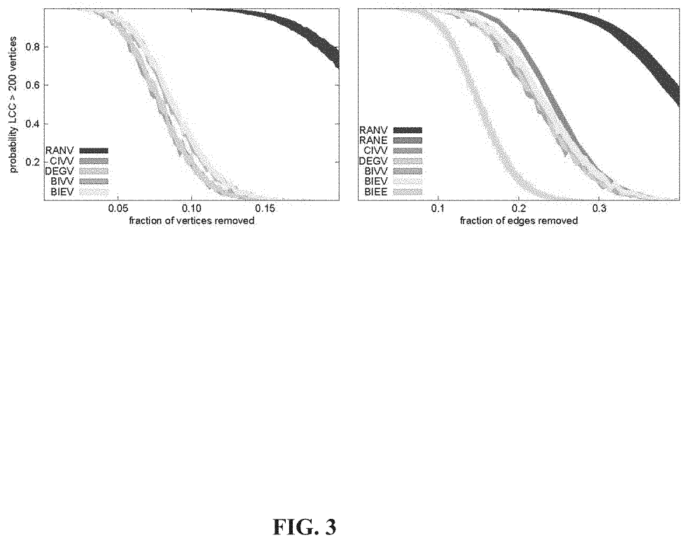

After removing top-ranked vertices from PLP, the fraction of 1000 ER-0.075 subgraphs that had more than 200 vertices in the LCC were computed. The results are shown in FIG. 3 as a function of the fraction of vertices or edges removed. Similar plots for size thresholds of 400 and 800 vertices, and for the SF and SF+PLP networks are discussed later. Error bands for all except RANV and RANE extend two estimated standard errors on either side, roughly a 95% confidence interval. Error bands for random ranking are the 5% and 95% quantiles of the median value from 100 different random rankings. To leading order in x, the probability that the largest ER-x cluster size exceeds k for a network with E edges is

$${R}_{LCC k + 1} = \frac{{n}_{k}}{( \begin{matrix}E \\ k\end{matrix} )} {x}^{k} + O ( {x}^{k + 1} ) , \qquad ( 5 )$$

where nₖ is the number of subgraphs with exactly k edges that are trees. Hence, with S samples, R_{LCC k} is not distinguishable from zero when

$${n}_{k} \leq ( \begin{matrix}E \\ k\end{matrix} ) {x}^{- k} / S . \qquad ( 6 )$$

In this example, even when R_{LCC200} is less than 0.001 and, hence, not distinguishable from zero with only 1000 samples, there may still be as many as nₖ≈10¹²⁶⁹ subtrees of size k. Only when nₖ vanishes, as happens in this case after removing 70% of the edges, is R_{LCC k} reduced to zero. Of course, the practical importance of small values of R_{LCC k} depends on the situation.

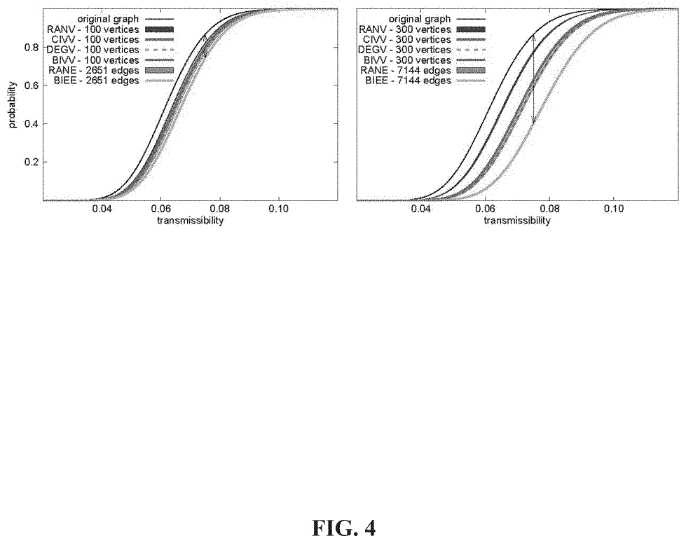

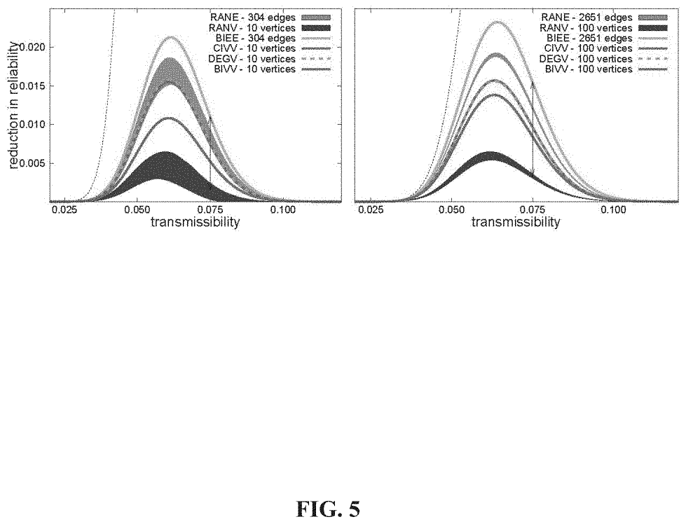

The probabilities displayed in FIG. 3 are, in effect, Monte-Carlo estimates of the reliability at x=0.075. Such estimates are not sensitive enough to identify the importance of individual edges or vertices, nor do they capture the dependence on transmissibility. FIG. 4 exhibits a higher-resolution Monte-Carlo estimate of reliability as a function of x fit to the known Bezier polynomial form of the function after removing either 100 or 1000 vertices. The number of Monte-Carlo samples was adjusted so that the estimate at each x had an estimated probable error of 0.002, and the resulting 95% confidence intervals around the curves in the figure are smaller than the width of the curves. The Birnbaum importance of a set of graph elements as a function of transmissibility is the difference between these curves, as shown in FIG. 5.

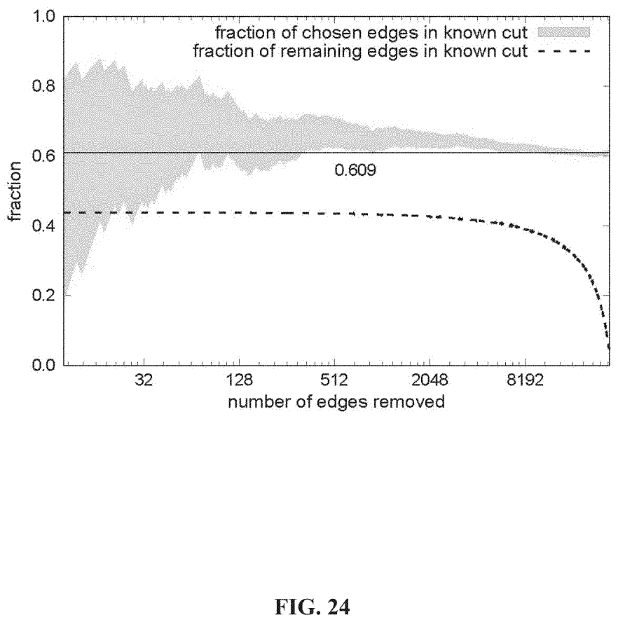

The correct sensitivity ranking for edges in PLP is not known, but there is no evidence for a cut smaller than the 17,500-edge cut designed into the network. Hence, it is expected that all the inter-community edges should be ranked higher than any intra-community edge. FIG. 24 exhibits the fraction of edges selected as most important by BEE that are inter-community edges. The mean over all edges removed is roughly 0.609. It is not yet clear how much of this error is due to sampling and truncation in estimating sensitivity and how much is due to the greedy approach to edge selection.

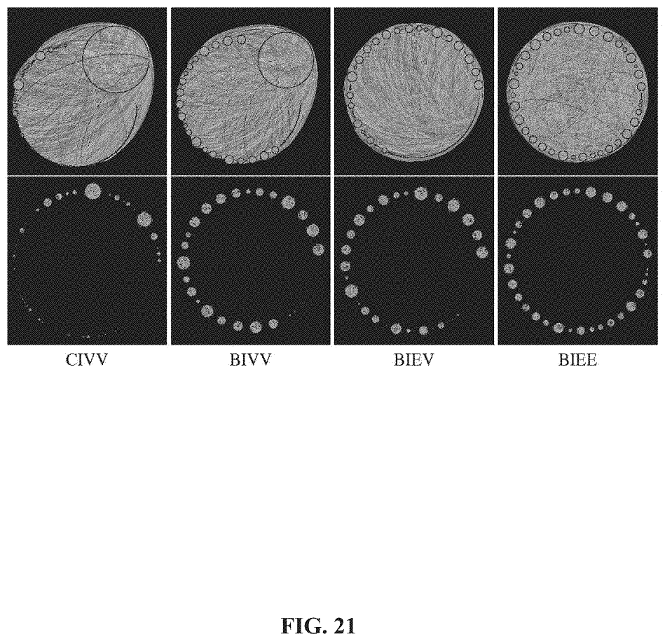

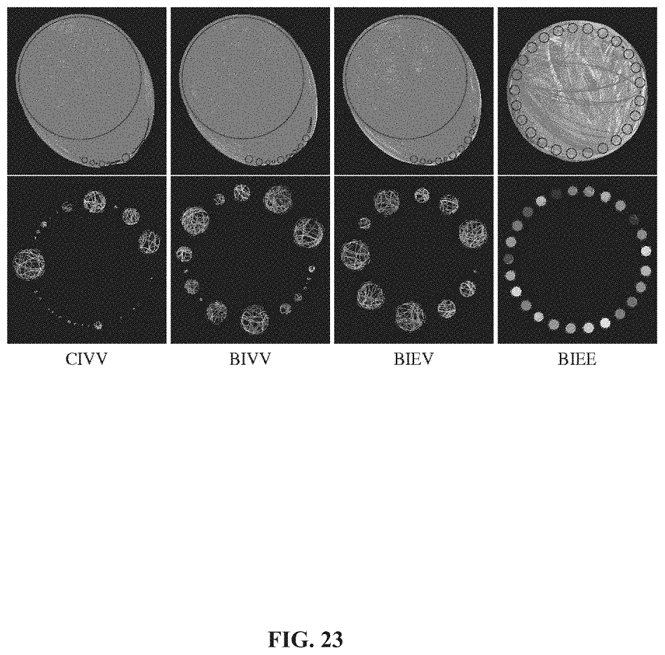

Table I gives descriptive statistics for the LCC₂₀₀ cuts found by each method for each network. Corresponding pictures of the networks and the graphs are shown in FIGS. 21-23. As expected, the edge cuts found by BIEE comprise distinctly fewer clusters than the vertex cuts found by CIVV or BIVV. The vertex cuts found by BIEV (degree-based vertex costs) can look like edge cuts, depending on network characteristics. The BIVV cuts comprise slightly, but systematically, fewer clusters than the CIVV cuts, and preserve more of the original network's edges, at a slight (<1%) cost in modularity.

TABLE 1
LCC₂₀₀ cut statistics. Statistics on the LCC₂₀₀ cuts
found by each method for each network.

| | | | non-isolated | edges | |
|---|---|---|---|---|---|
| Network | method | clusters | vertices | remaining | modularity |
| SF | CIVV | 1742 | 3636 | 3260 | 0.995 |
| | BIVV | 1364 | 3852 | 3644 | 0.988 |
| | BIEV | 234 | 3816 | 3590 | 0.967 |
| | BIEE | 221 | 4844 | 4877 | 0.966 |
| SF + | CIVV | 2015 | 3449 | 3154 | 0.996 |
| PLP | BIVV | 1224 | 4079 | 4483 | 0.988 |
| | BIEV | 1215 | 4105 | 4478 | 0.988 |
| | BIEE | 78 | 4978 | 7939 | 0.965 |
| PLP | CIVV | 3431 | 1666 | 1584 | 0.996 |
| | BIVV | 3371 | 1652 | 1645 | 0.994 |
| | BIEV | 3406 | 1631 | 1625 | 0.993 |
| | BIEE | 42 | 5000 | 12161 | 0.959 |

Discussion and Conclusions

The results above demonstrate that perturbative approximations to Birnbaum importance can accurately estimate the sensitivity of monotonic properties of a dynamical system to individual elements of its interaction network. The approach is extremely flexible yet its results are competitive with, and often improve upon, bespoke methods. The nature of these approximations suggest applications beyond sensitivity analysis, including numerical renormalization group studies, graph reduction, approximations to stochastic satisfiability problems, network design, explaining the performance of artificial neural networks, and optimal targeting under constrained resources.

Understanding how individual system constituents and the interactions among them contribute to aggregate dynamical phenomena is fundamental to network science. Unfortunately, in most analyses, the notion of contribution is often replaced with simple graph statistics; the actual dynamics, with simpler dynamics; actual interaction networks, with special families of random graphs; and provable approximation techniques, with heuristics. These simplifications typically result in methods that are restricted to unlabeled, unweighted, undirected, pairwise interactions and that, even so, ignore the contribution's dependence on dynamical parameters. The methods demonstrated herein are not subject to these restrictions and produce provably good approximations with controllable errors, albeit at an unavoidable cost in computational complexity. Moreover, they provide a unified perspective on canonical problems in different domains and suggest new ways of characterizing structure in networked systems.

There are many interesting, open questions related to determining the sensitivity of dynamics to elements of an interaction network. However, finding optimal approximations for a monotonic system just requires proper application of solutions to pieces of the puzzle that have been known for decades.

Networked Dynamical Systems

The dynamics of a networked dynamical system are encapsulated in a set of local functions that specify the conditional probability associated with each interaction. In principle, each local function could be a separate parameter in the dynamics; in practice, the same local function is often used at every vertex, often with the same parameter values. For example, the transition probabilities in physical systems are often determined by an overall coupling strength, sometimes modified by a vertex-specific “charge”. In general, a set of dynamical parameters \vec{x} and an interaction-dependent function \vec{ω} (\vec{x}) that gives the transition probability for each interaction as a function of the dynamical parameters are considered. Usually, dim(\vec{x})<<dim \vec{ω} (\vec{x}). The local functions are written as ω_{i,s′}(\vec{x}; s, s₁, . . . , s_{di}). This is a set of vertex-specific functions indexed by i and s′ that give the probability that vertex i will be in state s′ on the next time step given that it is currently in state s and its dᵢ neighbors in a dependency graph are currently in states s₁, . . . , s_{d}. For SIR dynamics, the local functions have the same symmetric functional form for all vertices:

$$\begin{matrix}{ω}_{i , S} ( {x}^{->} \text{;} S , {s}_{1} , … , {s}_{d} ) = {\prod }_{j = 1}^{{d}_{i}} [ 1 - {w}_{j , i} δ ( {s}_{j} , I ) ] \text{;} \\ {ω}_{i , I} ( {x}^{->} \text{;} S , {s}_{1} , … , {s}_{d} ) = 1 - {ω}_{i , S} ( {x}^{->} \text{;} S , {s}_{1} , … , {s}_{d} ) \text{;} \\ {ω}_{i , R} ( {x}^{->} \text{;} I , … ) = 1 \text{;} \\ all others = 0 ,\end{matrix} \qquad ( 7 )$$

where w_{j,i} is a weight associated with the edge from the j-th neighbor, i.e., the probability of transmission. Each local function gives the probability of a possible outcome of an interaction. Notice that in this approach, each interaction has a single deterministic outcome—stochasticity enters in the choice of which interactions occur.

Heterogeneous Weights

In physical systems, the concern is usually with nearly homogeneous interactions. In networked dynamical models, in contrast, it is natural to consider heterogeneity in interaction probabilities. For example, epidemiological models often take into account the heterogeneity that arises from individual characteristics such as age or behavior. Nonetheless, for simplicity of exposition and analysis, homogenous examples are considered here, although the methods are equally applicable to fully heterogenous systems.

For homogenous SIR dynamics, there is a single dynamical parameter, viz., the transmissibility x, and w_{j,i}∈{0, x, 1−x, 1} for all i, j. Hence, the examples ignore the distinction between dynamical parameters and conditional probabilities. Even for homogenous systems, though, the mapping can be non-trivial. For example, consider a two-site Ising model. Each vertex can be in one of two states, sᵢ=+1 or −1. The relative probability of two configurations c={s₁, s₂} and c′={s′₁, s′₂} in equilibrium is given by exp[−x(s₁s₂−s₁′s₂′)]. Hence the absolute probability of a configuration in equilibrium is

$${p}_{{s}_{1} {s}_{2}} = exp ( - {xs}_{1} {s}_{2} ) / 4 cosh x = \frac{1}{2} ( 1 - {s}_{1} {s}_{2} tanh x ) . \qquad ( 8 )$$

This equilibrium distribution can be obtained as the fixed point Δp₊₊=0 of a dynamical system given by the master equation

Δp₊₊=−2ωp₊₊+(1−ω)(p₊₋+p₋₊) (9)

where w=ω(x) is the probability of a transition from a configuration with s₂=s₁ to one with s₂≠s₁. When

$$ω ( x ) = \frac{1}{z} ( 1 + tanh x ) ,$$

the fixed point gives the correct value of p₊₊ for the equilibrium distribution.

Inducing the Interaction Hyper-Network from the Dependency Graph

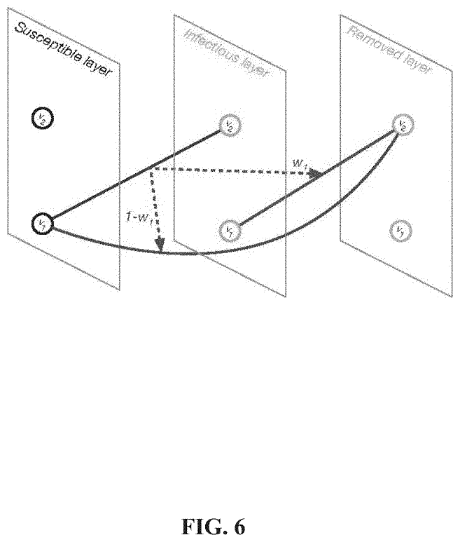

For homogenous SIR dynamics, the interaction network looks the same as the dependency graph. However, for dynamics such as complex contagions (30-32), in which interactions are not pairwise, or if more than one state plays a nontrivial role in the dynamics, representing the interaction network is more complicated. A multi-layer, directed hypergraph is used and is illustrated in FIG. 6 for the two possible interactions between a susceptible vertex and an infectious vertex under networked SIR dynamics. Each layer represents a possible state of the vertices. Each interaction is represented by a directed hyperedge (a dashed arrow) from a set of source vertices in specific states (connected by a solid line) to a set of destination vertices in specific states (also connected by a solid line). The local functions define the weights on each hyper-edge:

$${w}_{( \{ \text{?} , \text{?} , \text{?} \} \text{;} \{ \text{?} , \text{?} , \text{?} \} )} = \text{?} ( {x}^{->} \text{;} {s}_{a} , {s}_{b} , … ) \text{?} ( {x}^{->} \text{;} {s}_{a} , {s}_{b} , … ) . \\ \text{?} \text{indicates text missing or illegible when filed} \qquad ( 10 )$$

The sum of the weights on all arrows from a single source hypervertex must be unity.

Because SIR dynamics involve independent pairwise interactions, and only the I state plays a nontrivial role in the dynamics, they can be represented in a more familiar form by collapsing the interaction network onto a weighted, directed graph. A weight associated with edge (i, j) from vertex vᵢ to vⱼ represents the conditional probability of transmission from vᵢ to vⱼ, conditioned on vᵢ being in state I and vⱼ being in state S. That is, w_{i,j}=ω_{j,I}(\vec{x}; S, I). By assumption, each interaction is conditionally independent of the others. Moreover, in the examples here, the interaction probabilities are taken to be homogeneous, so the interaction network collapses still further into a simple, undirected, unweighted graph.

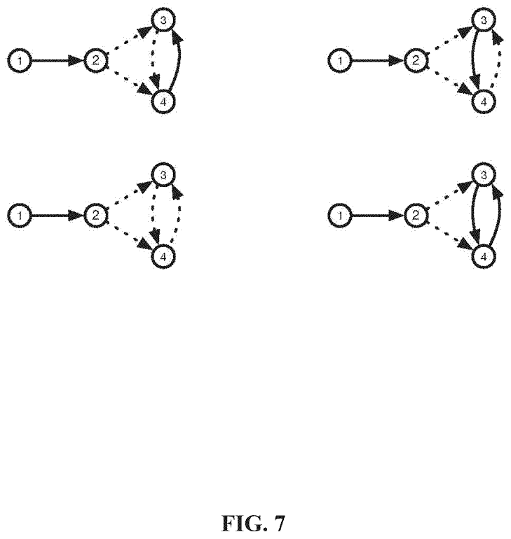

The semantic convention that an interaction “occurs” with a certain conditional probability is used, but the change of state implied by the interaction is only “completed” if the conditions are met. This convention allows for marginalizing correctly over the probabilities of interactions whose conditions are not met. For example, with the initial condition that vertex 1 is in state I and the others are in state S, the possible sets of interactions in FIG. 7 all lead to the same final configuration, viz., {v_{1,R}, v_{2,R}, v_{3,S}, v_{4,S}}, with vertices 1 and 2 in state R and vertices 3 and 4 in state S. The probability of the interactions in the top row are the same, x²(1−x)³, whereas the probabilities of the interaction sets in the bottom row are x(1−x)⁴ and x³(1−x)². The total probability for the four possible interaction sets is the sum of all four terms, or x(1−x)². Notice that this is the same result that would have been obtained by marginalizing over the probabilities of interactions 3→4 or 4→3, i.e., ignoring whether or not they occur, in the sense the term is used herein. Also notice that under a different initial condition, say vertex 3 but not vertex 1 in state I, the two sets of interactions on the right lead to a different configuration than the two on the left, and the total probability of that configuration depends on other possible interaction sets not shown here.

Moore-Shannon Reliability

For finite graphs in which each vertex has a finite number of states, the reliability is the sum of a finite number of terms, each of which is the product of a finite number of weights. For example, in SIR dynamics with homogeneous probability of transmission x, the probability that exactly k interactions occur is x^{k}(1−x)^{E-k} and the reliability is a polynomial in x of degree at most E. In this case, two-terminal reliability on an interaction network chosen from the family of “toy” networks in FIG. 8 is, by inspection:

$${R}_{𝒩 ( m , a , b ) , {𝒫}_{𝒮𝒯}} ( x ) = {x}^{b} + x [ 1 - {( 1 - {x}^{a} )}^{m} ] ( 1 - {x}^{b} ) . \qquad ( 11 )$$

It is useful to think of the property [symbol] as an order parameter that distinguishes two phases of a system: one in which the dynamics have the property and another in which they do not. As dynamical parameters such as coupling strength vary, the system is driven from one phase to another as the fraction of dynamical trajectories that exhibit [symbol] increases, typically in a nonlinear fashion. The change is not accomplished by smoothly changing one phase into another, but instead by changing the occupancies of the two discrete phases. Indeed, this is a natural representation of critical phenomena such as phase transitions in statistical physics. The reliability measures the relative occupancy of the two phases. Interesting phenomena can be expected in the critical region of nonlinear growth in reliability.

Reliability is not Submodular with Respect to Individual Edges

A set function ƒ: 2^{Ω}→R is submodular if and only if, for all X⊆Ω and x₁ ƒ=x₂ ∈Ω\X:

ƒ(X∪{X₁})+ƒ(X∪{x₂})≤ƒ(X∪{x₁,x₂})+ƒ(X). (12)

If Y⊆G is a crux, e₁≠e₂∈Y are single edges, and X≡Y\{e₁,e₂}, then by definition of a crux,

0=R_{X∪(e}_{₁}₎+R_{X∪(e}_{₂}₎<R_{X∪(e}_{₁}ₑ_{₂}₎+R_{X}=R_{Y}. (13)

Struts and Cuts

The property [symbol] partitions the set of configurations into two sets: the set of P-configurations, which have the property [symbol] , and its complement. [symbol] also partitions the power set of Interactions, 2^{G}, into two sets:
1. Struts are sets of interactions that lead to a [symbol] -configuration. That is, g⊂G is a strut if and only if [symbol] +(w)>0.
2. Cuts are sets of interactions whose complement does not lead to a [symbol] -configuration. That is, g⊂G is a cut if and only if [symbol] (\vec{w})=0.

For property [symbol] _{ST}, any set of edges that includes one or more paths from S to T is a strut and any set whose removal splits the graph into two or more connected components, none of which contains both S and T, is a cut.

Monotonicity and Cruxes

It remains to define monotonicity in general dynamical systems. Because all possible outcomes in the set of interactions are included, and unitarity on their weights is imposed, the definition is not as simple as for SIR dynamics. For example, although all the properties discussed herein are monotonic increasing in the interactions with probability w—i.e., those that transmit infection—they must be monotonic decreasing in the interactions with probability 1—w—those that do not.

The following slightly modified definition of monotonicity seems appropriate, although detailed investigation is beyond the scope of this work. Consider a small perturbation to the weights w^{t}ᵢ(ε)=wᵢ+σᵢε, where σᵢ=±1 or 0. Unitarity is maintained for any set of interactions if and only if the sum of the σ's across the set vanishes. Obviously, for this to be the case when any σ is non-zero, some σ's must be negative and some positive. Hence the interactions are partitioned into two disjoint sets: I₋, those for which dw′(ε)/dε<0; and I₊, those for which dw′(ε)/dε>0. A property [symbol] is monotonic under the perturbation w′ if and only if it is separately monotonic with opposite senses on I₊ and I₋. That is, both of the following conditions must be met:
1. if g is a strut with respect to [symbol] , then g∪e is also a strut for all e∈I₊;
2. if g is a cut with respect to [symbol] , then g∪e is also a cut for all e∈I₋.

It is expected that under this definition of monotonicity, the related SAT problem expressed either in terms of minimal struts or in terms of minimal cuts is also monotonic. In the collapsed representation of SIR dynamics, all the edges represent interactions in the set I₊, and this definition reduces to the one in the main text.

Monotonicity is a function of the combination of the interaction network, the dynamics, the pertutbation, and the property. Fortunately, most properties needed to answer common questions about sensitivity under most diffusive dynamics are monotonic on any interaction network under interesting perturbations. However, Girvan-Newman modularity is not a monotonic property under the usual definition. Consider two communities, {v₁, v₂} and {v₃, v₄, v₅}, Let G be the edge set {(v₁, v₂), (v₃, v₄), (v₄, v₅)} and consider two edges, an inter-community edge eₜ=(v₂, v₃) and a within-community edge e_{w}=(v₃, v₅). The modularities satisfy modularity(G∪e_{w})>modularity(G)>modularity(G∪eᵢ), as they were designed to do. If the communities were known a priori, the sets of within-community and intra-community edges would be likely candidates for I₊ and I₋, respectively.

As discussed herein, monotonic properties admit minimal struts and cuts, or s-cruxes and c-cruxes. Each member of the family of toy networks N (m, a, b) contains m+1 s-cruxes under [symbol] _{ST}: one with exactly b edges and m with exactly a+1 edges. The first is completely edge-disjoint from the others, and the others all share a single edge, A₀ in FIG. 8. Each member of the family contains b(1+a^{m}) c-cruxes, b with exactly 2 edges and ba^{m} with exactly m+1 edges. The first contains the edge A₀ and the others contain exactly one edge from each of the m sets}Aₖ₁, . . . , Aₖₐ}. Every c-crux contains exactly one edge from the set {B₁, . . . , B_{b}}.

For property [symbol] _{ST}, only the simple paths from S to T are minimal struts. Thus s-cruxes for [symbol] _{ST} have at least as many edges as the length of the shortest path from S to T, and no more than the diameter of G, and bounds on the reliability can be constructed with no more information about graph structure. For properties that require the size of the largest connected component to be at least N, only trees with N−1 edges are minimal struts. In this case, either the reliability vanishes or it is bounded below by x^{N-1} and above by (1−x)^{E-N+1}. When N=V, i.e., the entire graph is required to be connected, the Kirchoff matrix tree theorem (33, 34) allows the number of spanning trees t to be computed, which gives a better lower bound, tx^{N-1}.

Finding Cruxes

For finding cruxes that are special kinds of subgraphs such as simple paths, spanning trees, or minimal cuts (in the usual sense of the word), there are often highly optimized algorithms available. Described is a general search that requires O (n log n) queries to an oracle that evaluates whether a given graph is a strut or not. It is no doubt suboptimal on special cases, but is flexible enough to work for any monotonic property.

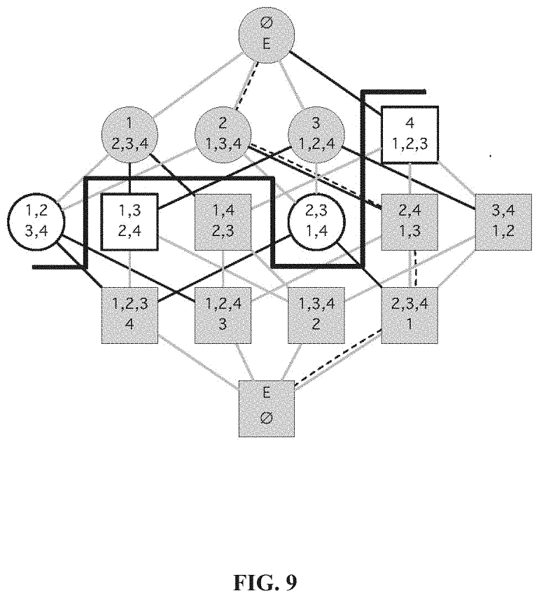

FIG. 9 shows all possible interaction subsets (i.e., subgraphs) of a system with only four interactions (i.e., edges), arranged in a lattice where the number of interactions present increases from top to bottom. For monotonic reliabilities, there is a separatrix—a continuous curve separating struts from cuts, like the one illustrated—with the property that every path through the lattice from the top to the bottom crosses the separatrix in exactly one place. All cruxes are subgraphs adjacent to the separatrix, but the converse is not true. S-cruxes can be found using Algorithm S1; a straightforward change provides an algorithm for c-cruxes.

```
Algorithm S1 Randomly select an s-crux.
Require: [symbol] , an interaction network
Require: [symbol]  (g), true if and only if g ⊆ [symbol]  produces a configuration with the desired property
  function FINDSCRUX( [symbol]  , [symbol] )
    cut ← θ; strut ← [symbol]
    found ← false
    while not found do [symbol]  search for separatix on random path between strut and cut
      while |strut| > |cut| + 1 do
        k ← (|strut| − |cut|)/2
        h ← set of k edges drawn at random from strut \ cut
        g ← cut ∪ h [symbol]  g interpolates on a random path between strut and cut
        if [symbol]  (g) then
          strut ← g
        else
          cut ← g
        end if
      end while [symbol]  strut and cut are adjacent to the separatrix, on opporiste sites of it
      found ← true
      for e ϵ strut do [symbol]  test for minimality
        if [symbol]  (strut \ e) then [symbol]  not minimal, restart search, replacing [symbol]  with strut \ e
          found ← false
          strut ← strut \ e
          cut ← θ
        end if
      end for
    end while
    return strut
  end function
```

Stochastic SAT Formulation

The amount that any particular s-crux would contribute by itself to the reliability is the probability that the interactions it comprises occur. In this example, the contribution of the s-crux with b edges to the reliability is x^{b}. However, a crux's contribution in the context of other cruxes is sub-additive, because the events represented by cruxes are not independent. That is, when there are two cruxes, the reliability is the probability that either of two events, E₁ and E₂ occurs, and

p(E₁∨E₂)=p(E₁)+p(E₂)−p(E₁∧E₂) (14)

≤p(E₁)+p(E₂). (15)

In general, if there are m s-cruxes, the reliability is the probability of a disjunction of events

E₁∨E₂∨ . . . ∨Eₘ, (16)

where E₁ is the event that the i-th s-crux is in the set of interactions. That is, Eᵢ itself is the compound event that every interaction in the crux occurs, viz.,

Eᵢ5eᵢ_{₁}∧eᵢ_{₂} . . . ∧eᵢ_{ₖ}, (17)

where eᵢₗ is the l-th interaction in the i-th crux. Hence, the expression in Eq. 16 is a logical combination of binary random events expressed in disjunctive normal form (DNF).

Inclusion-Exclusion Expansion

Iterating Eq. 14 produces the Inclusion-Exclusion expansion:

$$p ( {{⩔}_{i = 1}}^{m} {E}_{i} ) = {\sum }_{i = 1}^{m} p ( {E}_{i} ) - {\sum }_{i > j = 1}^{m} p ( {E}_{i} ⩓ {E}_{j} ) + {\sum }_{i > j > k = 1}^{m} p ( {E}_{i} ⩓ {E}_{j} ⩓ {E}_{k} ) - … + {( - 1 )}^{m + 1} p ( {E}_{1} ⩓ {E}_{2} ⩓ … ⩓ {E}_{m} ) . \qquad ( 18 )$$

Eᵢ∧Eⱼ is a compound event that is the conjunction of all the basic events in the union of cruxes i and j. If the number of interactions in the compound event E is denoted |E|, then for Eᵢ ƒ=Eⱼ,

max(|Eᵢ|,|Eⱼ|)<|Eᵢ∧Eⱼ|≤|Eᵢ|+|Eⱼ|. (19)

In this example, the probability of each basic event eᵢ is x, so p(E)=x^{|E|} and the Inclusion-Exclusion expansion becomes an expansion in powers of x. The terms arising from a conjunction of d events may contain a range of powers of x, but the range is bounded. If kₘᵢₙ(d) and kₘₐₓ(d) denote, respectively, the smallest and largest exponents encountered in the expansion of conjunctions of d events, then Eq. 19 gives:

kₘᵢₙ(d−1)+1≤kₘᵢₙ(d)≤k_{mace}(d)≤kₘₐₓ(d−1)+kₘₐₓ(1). (20)

That is, kₘᵢₙ(d)≥d. In other words, the Inclusion-Exclusion expansion truncated at depth d gives the first d terms of the power series expansion in x correctly (and potentially many more).

More generally, \vec{ω}(\vec{x}) can be expanded in a power series at x:=0. Substituting this power series into an Inclusion-Exclusion expansion truncated at depth D) yields a power series for the reliability in \vec{x} that is exact up to terms in x^{D}. Algorithm S2 illustrates the process.

```
Algorithm S2 Contribution of a set of events A to p(A ∨ X), truncated at depth D.
Require: A, X, sets of sets of basic events
Require: p(e₁ ∧ . . . ∧ eₙ), probability of the conjunction of any n basic events
Require: D, depth of expansion
  function CONTRIBUTION (A, X, p, D)
    prob ← 0
    for i ← 1, min(D, |A|) do
      for b ϵ {B ⊆ A: |B| = i} do [symbol]  all combinations of exactly i sets from A
        prob ← prob + (−1)ⁱ⁺¹ p(b)
        for j ← 1, min(D − i,|X|) do
          for y ϵ {Y ⊆ X : |Y| = j} do [symbol]  all combinations of exactly j sets from X
            prob ← prob + (−1)^{i+j+1}p(b ∧ y)
          end for
        end for
      end for
    end for
    return prob
  end function
```

Reliability is Submodular with Respect to Cruxes

If X⊂S, the set of all s-cruxes, and sϵS\X is an individual crux then

p(X)<p(X∨s)≤p(X)+p(s). (21)

Hence for s₁≠s₂ϵS\X,

$$\begin{matrix}R ( X ⋃ \{ {s}_{1} , {s}_{2} \} ) + R ( X ) = p ( X ⩔ {s}_{1} ⩔ {s}_{2} ) + p ( X ) = 2 p ( X ) + p ( {s}_{1} ) + p ( {s}_{2} ) - p ( X ⩓ {s}_{1} ) - p ( X ⩓ {s}_{2} ) ) - p ( {s}_{1} ⩓ {s}_{2} ) & ( 22 ) \\ + p ( X ⩓ {s}_{1} ⩓ {s}_{2} ) = p ( X ⩔ {s}_{1} ) + p ( X ⩔ {s}_{2} ) & ( 23 ) \\ + p ( X ⩓ {s}_{1} ⩓ {s}_{2} ) - p ( {s}_{1} ⩓ {s}_{2} ) & ( 24 ) \\ \leq p ( X ⩔ {s}_{1} ) + p ( X ⩔ {s}_{2} ) & ( 25 ) \\ \leq R ( X ⋃ \{ {s}_{1} \} ) + R ( X ⋃ \{ {s}_{2} \} ) . & ( 26 )\end{matrix}$$

Cut/Strut Duality

It is always possible to express the probability of a disjunction of events in terms of its complement:

$$\begin{matrix}p ( {E}_{1} ⩔ {E}_{2} ⩔ … ⩔ {E}_{m} ) = 1 - p ( \overline{{E}_{1} ⩔ {E}_{2} ⩔ … ⩔ {E}_{m}} ) & ( 27 ) \\ = 1 - p ( \overline{{E}_{1}} ⩓ \overline{{E}_{2}} ⩓ … ⩓ \overline{{E}_{m}} ) & ( 28 ) \\ = 1 - p ( {{⩓}^{m}}_{i = 1} ( {\overline{e}}_{{i}_{1}} ⩔ {\overline{e}}_{{i}_{2}} … ⩔ {\overline{e}}_{{i}_{m}} ) ) & ( 29 )\end{matrix}$$

Rearranging terms in the last expression so that it is in DNF can be computationally expensive, but in principle it leaves an expression for the reliability in terms of cuts, which can be simplified into an expression in terms of c-cruxes. From this, it is clear that a cut contains at least one element of every s-crux and vice versa. This is the duality at the heart of the max-flow min-cut theorem (35).

The DNF does not have to be converted in terms of s-cruxes to one in terms of c-cruxes explicitly. Instead, c-cruxes can be sampled directly using a slight modification of the algorithm for sampling s-cruxes. With the reliability expressed in terms of cuts, the Inclusion-Exclusion expansion is an expansion in products of 1−p(e). In this example, the Inclusion-Exclusion expansion becomes a polynomial in powers of 1−x. Truncating the expansion gives a Taylor series approximation around the point x=1.

Graph Construction

The reliability is completely determined either by the set of s-cruxes or by the set of c-cruxes. For any graph G and any monotonic property [symbol] , a graph G*(G, [symbol] ) can be constructed and vertices S and T in G⁺ for which R_{G,} [symbol] =R_{G}_{⁺}_{,} [symbol] _{S}_{ᵢ}_{T} can be identified. Algorithm S3 provides a constructive proof by treating the s-cruxes of G under [symbol] as paths from S to T in a new graph. Thus two-terminal reliability is in a sense a “universal” problem.

Moreover, a natural dual to G under [symbol] can be defined and constructed. Notice that negating the property P interchanges the roles of struts and cuts. Applying the construction in Algorithm S3 to c-cruxes instead of s-cruxes, a dual graph G(G, [symbol] ) can be generated. These graphs are related by their reliability:

[symbol]

= [symbol] =1− [symbol] (30)

Finally, a reduced graph with similar reliability can be constructed by applying the construction to a sample of s-cruxes instead of the full set. This is an analogue of the renormalization group program in statistical physics. Since the constraint is on reliability, it is not clear how well such a reduced graph would reproduce any feature of the dynamics other than [symbol] and sensitivity of [symbol] to network topology.

Bernstein Interpolation

The reliability is a finite-degree polynomial ƒ: [0, 1]ⁿ→[0, 1], where n+1 is the number of interaction probabilities in the system. Without loss of generality,

```
Algorithm S3 Construct a graph whose s-cruxes under [symbol] _{ST} match a given set,
Require: C, a set of s-cruxes (sets of edges) for property [symbol]  on interaction network [symbol]
  function CONSTRUCTGRAPH (C)
    Create a vertex S
    label(S) ← C
    PUSH(stack,S)
    while stack is not empty do
      V ← POP(stack); L ← label(V); N ← number of edges in the union of cruxes in L
      for i ← 1, N do [symbol]   For each edge appearing in any crux in L
        Create a vertex V¹
        L ← {c ϵ L : eᵢ ∉ c} [symbol]  Remove cruxes that contain edge i from L
        label(V¹) ← U_{c ϵL : ei ϵc} c \ eᵢ [symbol]  Remove cruxes that do not contain edge i [symbol]
              and edge i itself from remaining cruxes in label(V¹)
        merged ← false
        for all V^{p} ≠ V¹ do
          if label(V¹) = label(Vⁿ) then
            identify V¹ and Vⁿ
            merged ← true
          end if
        end for
        if not merged then
          PUSH (stack,V¹)
        end if
      end for
    end while
  end function
```

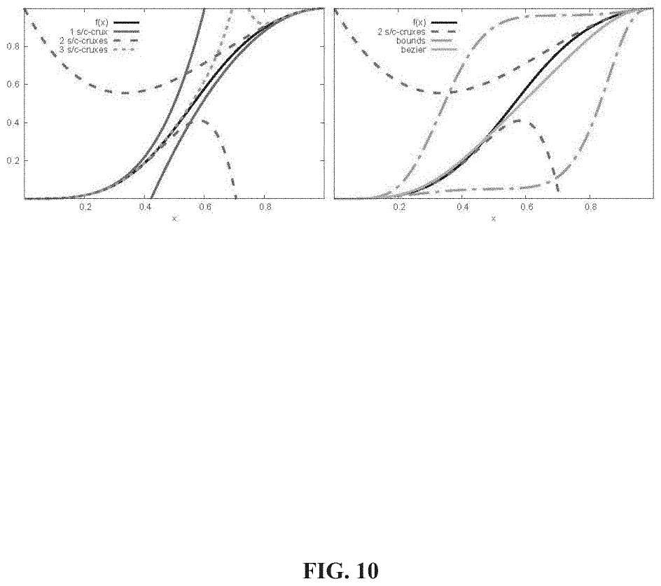

here n=1 is assumed for simplicity. In particular, the reliability is bounded above and below and, for a monotonic property, it is monotonic. The left panel of FIG. 10 illustrates the problems inherent to using an alternating series approximation. Truncated Taylor series expansions do not respect either the bounds or the monotonicity of ƒ. The goal is to find an interpolating polynomial between the Taylor series at x=0 and x=1 that is bounded and monotonic and agrees as much as possible with the Taylor series at each end. The Bernstein polynomials B(N,k,x)≡(Nk) x^{k}(1−x)^{N-k} provide a complete, but not orthogonal, basis for polynomials of degree N. As Moore and Shannon implicitly assume, the Bernstein polynomials provide a natural basis for the reliability. It is also possible to restrict the Bernstein coefficients to values that represent only bounded, monotonic polynomials.

This interpolation problem is distinguished from two other common uses of the Bernstein basis:
1. In computer-aided graphics, intuitively specifying a smooth curve whose form is controlled by placing “control points” in a plane. The results are known as Bezier curves. The curve lies within the convex hull of the control points. Bezier curves are useful in part because of the stability and simplicity of an evaluation algorithm developed by de Casteljau. Although it requires O(n²) operations, it uses recurrence relations for binomial coefficients to avoid underflow.
2. Approximating a continuous function ƒ(x) as Σdk=₀ƒ(k/d)B(d,k,x), the so-called Bernstein polynomial. This approximation is uniformly convergent in the limit as d→∞.

The goal, instead, is to find a polynomial of degree N whose first k₁ derivatives at x=0 and first k₂ derivatives at x=1 match known values. That is, \vec{ƒ}(x)≡ΣNk=₀\vec{β}ₖB(N,k,x) is sought for a fixed N such that

$$\frac{{d}^{k} \hat{f}}{{dx}^{k}} {\vert}_{x = 0} = k \text{\textbar} {α}_{k} , \text{∀} k \leq {k}_{1} \qquad ( 31 )$$

and simultaneously

$$\frac{{d}^{k} \hat{f}}{{dx}^{k}} {\vert}_{x = 0} = k \text{\textbar} {α}_{k} , \text{∀} k \leq {k}_{2} . \qquad ( 32 )$$

A little algebra gives the solution to Eq. 31:

$$\begin{matrix}{β}^{{\hat{}}^{->}} = T {α}^{->} & ( 33 ) \\ with {T}_{jk} ≡ ( \begin{matrix}j \\ k\end{matrix} ) / ( \begin{matrix}N \\ k\end{matrix} ) . & ( 34 )\end{matrix}$$

Similarly, if f̅(x)≡ΣNk=₀β̅ₖB(N,k,1−x) then Eq. 32 is satisfied by \vec{β}=T\vec{α}.

Since T is lower triangular, Eqs. 31 and 32 do not constrain the values of \hat{β}ₖ for k>k₁ or the values of β̅ₖ for k>2. Then, using a symmetry of the Bernstein polynomials B(N,k,x)=B(N,N−k,1−x), both sets of constraints can be satisfied simultaneously by combining the two estimates into ƒ*=ΣNk=₀βₖB(N,k,x), where,

$${β}_{k} ≡ \{ \begin{matrix}{\hat{β}}_{k} & k \leq min ( {k}_{1} , N - {k}_{2} ) \\ {\overline{β}}_{N - k} & k \geq max ( {k}_{1} , N - {k}_{2} ) \\ \frac{1}{2} ( {\hat{β}}_{k} + {\overline{β}}_{N - k} ) & min ( {k}_{1} N - {k}_{2} ) < k < max ( {k}_{1} , N - {k}_{2} )\end{matrix} . \qquad ( 35 )$$

When k₁+k₂≤N, the last case does not occur and the Bezier coefficients are underdetermined. In that case, it is possible to interpolate coefficients between the known ones or fit the polynomial with N′=k₁+k₂+1. When k₁+k₂>N+1, the coefficients are overdetermined. If the derivatives are known exactly, βₖ=β̅_{N-k} where they overlap; if the derivatives are estimates, a weighted average is a reasonable choice. Tight bounds on a monotonic increasing reliability as a function of x can be constructed by assuming any unspecified coefficients are equal to βₖ₁ (lower bound) or βₖ₂ (upper bound)—This is not immediate, but follows in this application from a non-negativity constraint on the coefficients themselves due to their interpretation as probabilities. The right panel of FIG. 10 exhibits the bounds and the interpolation constructed above for the D=2 expansion of the ST-reliability for the N (6, 3, 3) network.

Reliability for finite systems is a multinomial in the dynamical parameters. For homogeneous SIR dynamics, it reduces to a polynomial in x. It can be expressed as a Bezier polynomial of the form:

$$R ( x ) = {\sum }_{i = {k}_{-}}^{{k}_{+}} {β}_{i} ( \begin{matrix}E \\ i\end{matrix} ) {{x}^{i} ( 1 - x )}^{E - i} , \qquad ( 36 )$$

with 0≤k₋<k₊≤E. In this “universal” form, the following interpretations are independent of property and network, as long as the property is monotonic:
k₋ is the size of the smallest strut.
βₖ_{_{−}}(_{Ek}_{_{−}}) is the number of smallest strust.
E−k₊ is the size of the smallest cut.
(1−βₖ₊) (_{Ek+}) is is the number of smallest cuts.

The Moore-Shannon network reliability is clearly related to Gao et al.'s concept of “resilience” (36), and these interpretations may be helpful in clarifying the relationship. However, as illustrated below, the reliability clearly depends on network structure as well as dynamics, whereas it is asserted that resilience is independent of network structure. Thus, it can be suspected that the proposed resilience function is universal only because it ignores terms other than k₋ and k₊.

Birnbaum Importance

For dynamics in which a particular interaction can occur only once, e.g., SIR dynamics, the Birnbaum importance of each edge is an affine function of its probability. If the same interaction can occur at each time step, it may appear with power T. For example, to transmit malaria, a mosquito must bite twice: once to infect the mosquito and once to infect another human. In a model representing each bite as an interaction, the probability of biting enters as a square. When each event can occur only once, the reliability is a multilinear function of the weights, and B(g)=\vec{w}^{⊥}(g) S, where

$${w}_{i}^{⊥} ( g ) ≡ \{ \begin{matrix}{w}_{i} & i ∈ 𝒢 \backslash g \\ 0 & else\end{matrix} . \qquad ( 37 )$$

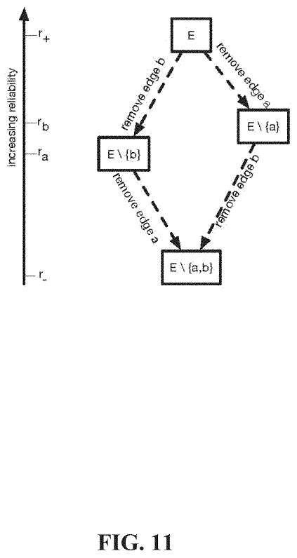

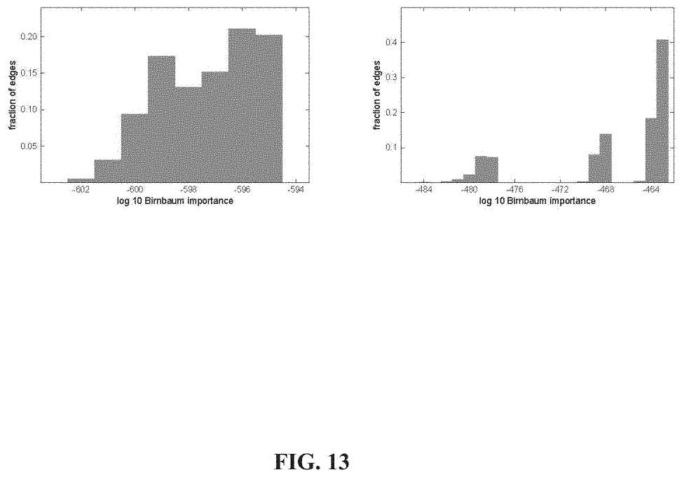

The diagram in FIG. 11 suggests a numerically stable way of ranking graph sets by Birnbaum importance. Direct computation of relative importance from the definition requires estimating r₊, rₐ, and r_{b} to find (r₊−rₐ)−(r₊−r_{b}). However, as illustrated by the distributions of scores in FIGS. 1 and 13, the difference r₊−rₐ is often extremely small and this approach suffers a severe loss of precision. Instead, when only the sign or relative magnitude of the difference is needed, as is the case in ranking, only the cruxes that contribute to this difference are used as in Algorithm S4, ignoring the “background”, r₊.

```
Algorithm S4 Evaluate sign of relative Birnbaum importance of two sets of interactions.
Require: [symbol]  , an interaction network
Require: [symbol] , true if and only if its argument produces a configuration with the desired property
Require: _{gA}, _{gB}, subsets of [symbol]
Require: \vec{w}(\vec{x}), probability of each interaction as a function of dynamical parameters \vec{x}
Require: S, the number of sample cruxes to use
  function BI( [symbol]  , [symbol] , g_{A}, g_{B}, \vec{w}(\vec{x}), S)
    inAandNotB ← ∅; inBandNotA ← ∅; inN either ← ∅
    while i < S do [symbol]  determine which of a sample of S cruxes are relevant
      crux ← FINDSCRUX( [symbol]  , [symbol]   )
      inA ← (crux ⊆ g_{A})
      inB ← (crux ⊆ g_{B})
      if inA and not inB then
        inANotB ← (inAandNotB U {crux})
      else if inB and not inA then
        inBNotA ← (inBandNotA U {crux})
      else if not (inA or inB) then
        inNeither ← (neither U {crux})
      end if
    end while
    R_{A}(\vec{x}) ← CONTRIBUTION(inAandNotB, inNeither,\vec{w}(\vec{x})))
    R_{B}(\vec{x}) ← CONTRIBUTION(inBandNotA, inNeither,\vec{w}(\vec{x}))
    return R_{A}(\vec{x}) − R_{B}(\vec{x})
  end function
```

Seriality

If an element occurs in every crux, its Birnbaum importance is equal to the reliability. If m cruxes are identical except for one element, then in the limit as x→0, the Birnbaum importance of any one of those distinguishing elements approaches 1/m of the reliability. Colloquially, it might be said that in the first case, the element is serial: every strut must “pass through” that element. In the second case, it would be said that the element is parallel: every strut makes the same contribution to the reliability, and all the contributions are independent. Hence the ratio of Birnbaum importance to reliability, which is in the interval [0, 1], measures whether the element's contribution to the dynamics is more serial or parallel. It is a normalized version of betweenness that takes into account the dynamics M and its parameters and the property [symbol] .

Results

Test networks: toys, scale free (SF), planted I-partition (PLP), and scale-free planted 1-partition (SF+PLP)

Below is a report of results on four networks:
1. A family of “toy” networks and their duals defined by three parameters (m, a, b), with a≥b, whose reliability for transmitting a signal from a vertex S to a vertex T can be expressed in closed form. The networks are illustrated in FIG. 8. Each network represents a parallel-series “motif” of the sort that could be expected to be embedded often in large, complex networks.
2. SF is a 5000 vertex network whose degree distribution is roughly d⁻². It is in the class of random networks used by Morone & Makse as test cases.
3. PLP is also a 5000 vertex network, but it is a planted 1-partition graph or stochastic blockmodel (37, 38). PIP contains 25 planted partitions, each of size 200 vertices. Each vertex has on average 7 edges connecting it to other partitions and 9 connecting it to other vertices within the same partition. There is thus a 17,500 edge LCC₂₀₀ cut in the graph. PLP was chosen because which edges must be removed to separate it into components with size no larger than 200 is known and because it is much more difficult to shatter than SF.
4. SF+PLP also contains 25 planted partitions, each of size 200 vertices, but its degree distribution is identical to that of SF. It could be considered a random graph, but one drawn from a small, vaguely-specified set of highly structured networks, with the following properties induced by the method of construction:
   Every vertex has at least one inter-partition edge, hence every vertex is on the boundary between two partitions.
   At most one vertex in each partition has two inter-partition edges, to ensure that the within-partition degree distribution is graphical.
   The high-degree vertices are dealt to the partitions in a round-robin fashion. As a result, each partition has one vertex with degree between 39 and 152 and another with degree between 26 and 39.
   The within-partition graphs are constructed by an algorithm that minimizes assortativity by degree, i.e. low-degree vertices are connected to high-degree vertices.
   The inter-partition network is a degree-regular random graph.

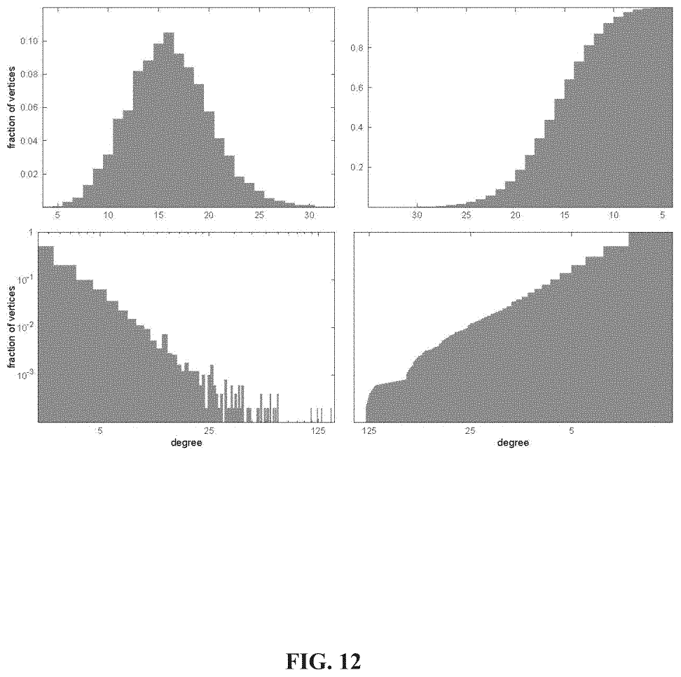

Degree distributions for the SF, PLP, and SF+PLP are shown in FIG. 12: The SF and PLP networks provide complementary tests of vertex- and edge-ranking: the easiest way to shatter the SF network is to remove vertices in order of degree, i.e. hubs first; the easiest way to shatter the PLP network is to remove inter-partition edges. The SF+PLP graph, as its name implies, was constructed to provide an intermediate between the two, which reduces the correlation between importance rank and degree. There is an LCC₂₀₀ cut of size 1248 edges planted in the network, but it is not necessarily the smallest LCC₂₀₀ edge cut, nor is it obvious what the minimum LCC₂₀₀ vertex cut is. On one hand, although there are still hubs in this network, they are irrelevant for the purposes of finding the planted partitions; on the other hand, every degree-2 vertex (which constitutes almost half the network) could arguably belong to either of two planted partitions. Since complex networks are not a priori drawn from one or the other network model, a technique that can only handle one or the other is not sufficient.

Closed Form Expressions for Toy Networks

For the three-parameter family of toy networks shown in FIG. 8, the relative Birnbaum importance of edges A₀ and B₁ changes sign at a critical point x_{c}. Moreover, the number of s-cruxes and c-cruxes, the Taylor series expansions, and the Bernstein coefficients can all be computed exactly for each member of the family. Estimating the location of the critical point is a stringent test of evaluating the Birnbaum importance, and allows us to explore the effects of sample size and depth on approximation error.

The minimal struts for [symbol] _{ST} on N (m=a=b=2), i.e., the simple paths from S to T, are:

S={{A₀,A₁₁,A₁₂},{A₀,A₂₁,A₂₂},{B₁,B₂}}. (38)

This set of struts induces a satisfiability problem in terms of the corresponding basic events

R(x)=p((a₀∧a₁₁∧a₁₂)∨(a₀∧a₂₁∧a₂₂)∨(b₁∧b₂). (39)

The power set of S contains 2³−1=7 non-empty sets of struts. The sets and the cardinalities of their unions are shown in Table 2. From this table, the complete Inclusion-Exclusion expansion of Eq. 39 can be read off:

R(x)=p((b₁∧b₂)+p(a₀∧a₁₁∧a₁₂)+p(a₀∧a₂₁∧a₂₂)

TABLE 2
The non-empty sets of interactions in the power set of S, the number
of struts they represent, and the number of interactions in them.

| interactions in cut combinations | # struts | # interactions |
|---|---|---|
| { [symbol] , [symbol] } | 1 | 2 |
| { [symbol] , [symbol] , [symbol] } | 1 | 3 |
| { [symbol] , [symbol] , [symbol] } | 1 | 3 |
| { [symbol] , [symbol] , [symbol] , [symbol] , [symbol] } | 2 | 5 |
| { [symbol] , [symbol] , [symbol] , [symbol] , [symbol] } | 2 | 5 |
| { [symbol] , [symbol] , [symbol] , [symbol] , [symbol] } | 2 | 5 |
| { [symbol] , [symbol] , [symbol] , [symbol] , [symbol] , [symbol] , [symbol] } | 3 | 7 |

−p(a₀∧a₁₁∧a₁₂∧b₁∧b₂)−p(a₀∧a₂₁∧a₂₂∧b₁∧b₂)

−p(a₀∧a₁₁∧a₁₂∧a₂₁∧a₂₂)

+p(a₀∧a₁₁∧a₁₂∧a₂₁∧a₂₂∧b₁∧b₂) (40)

and the Taylor series at x=0;

R(x)=x²+2x³−3x⁵+x⁷. (41)

Eq. 11 reduces to this power series for m=a=b=2. From the coefficients of the Taylor series at x=0 the coefficients of the Bernstein polynomial can be computed:

$$\begin{matrix}{β}^{->} = T {α}^{->} & ( 42 ) \\ = ( \begin{matrix}1 \\ 1 / 7 \\ 1 / 21 \\ 1 / 35 \\ 1 / 35 \\ 1 / 21 \\ 1 / 7 \\ 1\end{matrix} ) ( \begin{matrix}1 & & & & & & & \\ 7 & 1 & & & & & & \\ 21 & 6 & 1 & & & & & \\ 35 & 15 & 5 & 1 & & & & \\ 35 & 20 & 10 & 4 & 1 & & & \\ 21 & 15 & 10 & 6 & 3 & 1 & & \\ 7 & 6 & 5 & 4 & 3 & 2 & 1 & \\ 1 & 1 & 1 & 1 & 1 & 1 & 1 & 1\end{matrix} ) ( \begin{matrix}0 \\ 0 \\ 1 \\ 2 \\ 0 \\ - 3 \\ 0 \\ 1\end{matrix} ) & ( 43 ) \\ = {( 0 , 0 , \frac{1}{21} , \frac{1}{5} , \frac{18}{35} , \frac{19}{21} , 1 , 1 )}^{T} & ( 44 )\end{matrix}$$

That is, Eq. 41 can also be written:

R(x)=x²(1−x)⁵+7x³(1−x)⁴+18x⁴(1−x)³+19x⁵(1−x)²+7x⁶(1−x)+x⁷. (45)

To express the reliability in terms of 1−x, substitute y=1−x into Eq. 41:

$$R ( x ) = {x}^{2} + x [ 1 - {( 1 - {x}^{2} )}^{2} ] ( 1 - {x}^{2} ) = {( 1 - y )}^{2} + ( 1 - y ) [ 1 - {( 1 - {( 1 - y )}^{2} )}^{2} ] ( 1 - {( 1 - y )}^{2} ) = 1 - 2 {y}^{2} - 7 {y}^{3} + 20 {y}^{4} - 18 {y}^{5} + 7 {y}^{6} - {y}^{7} \qquad ( 46 )$$

There are 10 minimal cuts for this graph:

$$\begin{matrix}\{ {B}_{1} , {A}_{0} \} & \{ {B}_{1} , {A}_{11} , {A}_{21} \} & \{ {B}_{2} , {A}_{11} , {A}_{21} \} \\ \{ {B}_{2} , {A}_{0} \} & \{ {B}_{1} , {A}_{11} , {A}_{22} \} & \{ {B}_{2} , {A}_{11} , {A}_{22} \} \\ & \{ {B}_{1} , {A}_{12} , {A}_{21} \} & \{ {B}_{2} , {A}_{12} , {A}_{21} \} \\ & \{ {B}_{1} , {A}_{12} , {A}_{22} \} & \{ {B}_{2} , {A}_{12} , {A}_{22} \}\end{matrix} , \qquad ( 47 )$$

and thus 1023 non-empty members of the power set. A few of the 55 terms in the Inclusion-Exclusion expansion for cuts truncated at depth D=2 are shown in Table 2. Construction of the full SAT problem in DNF and the Inclusion-Exclusion expansion for cuts is left as an exercise for the reader, but the Taylor series coefficients at x=1 can be read off Eq. 46. From this Taylor series the following can be constructed:

$${β}^{{\_}^{->}} = {T ( 1 , 0 , - 2 , - 7 , 20 , - 18 , 7 , - 1 )}^{T} = {( 1 , 1 , \frac{19}{21} , \frac{18}{35} , \frac{1}{5} , \frac{1}{21} , 0 , 0 )}^{T} . \qquad ( 48 )$$

As shown above, β̅ₖ=β_{N-k}.

When edge A₀ is removed, the reliability decreases to x^{b}; when edge B₁ is removed, the reliability decreases to x[1−(1−x⁰)^{m}]. Hence,

B(A₀)=x[1−(1−x^{a})^{m}](1−x^{b}) (49)

B(B₁)=x^{b}{1−x[1−(1−x^{a})^{m}]} (50)

B(A₀)−B(B₁)=x[1−(1−x^{a})^{m}]−x^{b} (51)

TABLE 3
A few of the non-empty sets of interactions in the power set of C, the
number of cuts they represent, and the number of interactions in them.

| interactions in cut combinations | # cuts | # interactions |
|---|---|---|
| { [symbol] , [symbol] , [symbol] } | 2 | 3 |
| { [symbol] , [symbol] , [symbol] , [symbol] } | 2 | 4 |
| { [symbol] , [symbol] , [symbol] , [symbol] } | 2 | 4 |
| { [symbol] , [symbol] , [symbol] , [symbol] , [symbol] } | 2 | 5 |
| { [symbol] , [symbol] , [symbol] , [symbol] , [symbol] , [symbol] } | 2 | 6 |

Notice that any edge's importance vanishes when x=0 or x=1, as it must unless the edge itself is a cut. The Birnbaum importance thus cannot be used to rank elements in these deterministic cases. The difference B(A₀)−B(B₁) changes sign at x_{c}, the solution to:

1−x_{c}^{b-1}=(1−x_{c}^{a})^{m}. (52)

Birnbaum Importance

The distributions of scores for edges in the SF and SF+PLP net-works, analogous to the distribution in FIG. 1 are shown in FIG. 13.

Giant Component Size Vs Vertices Removed

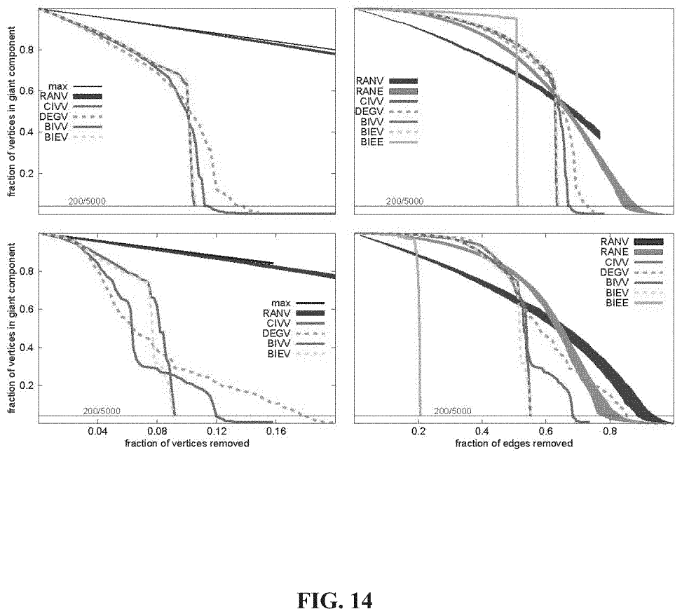

The effects of vertex or edge removal on the size of the giant component (GC) in the SF and SF+PLP networks are shown in FIG. 14.

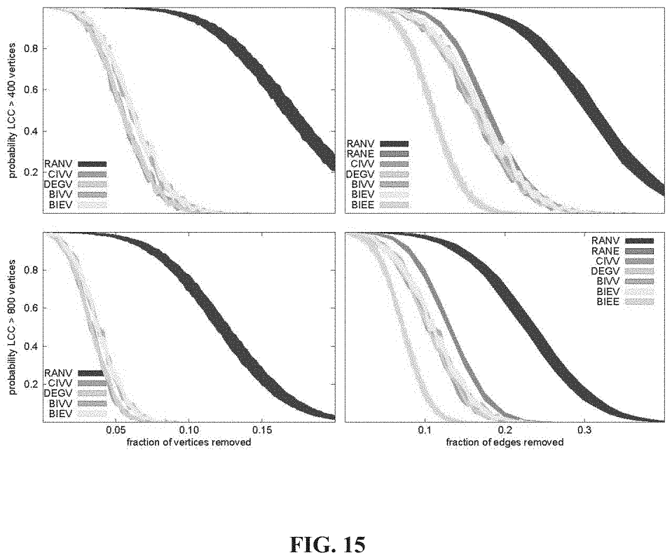

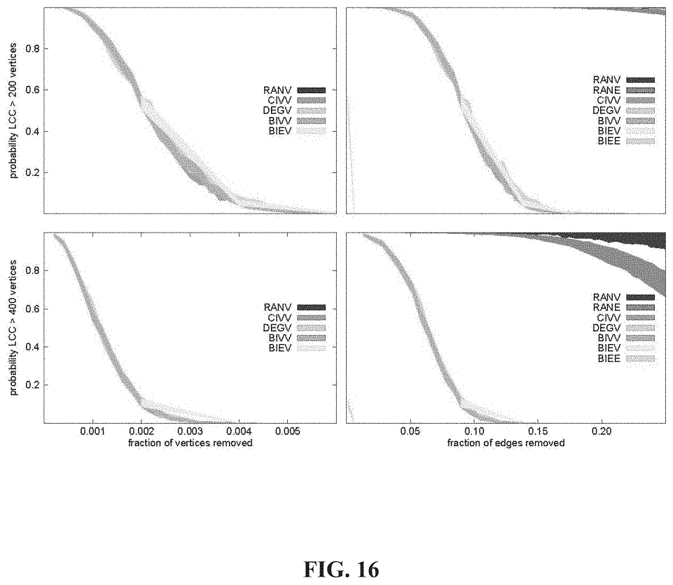

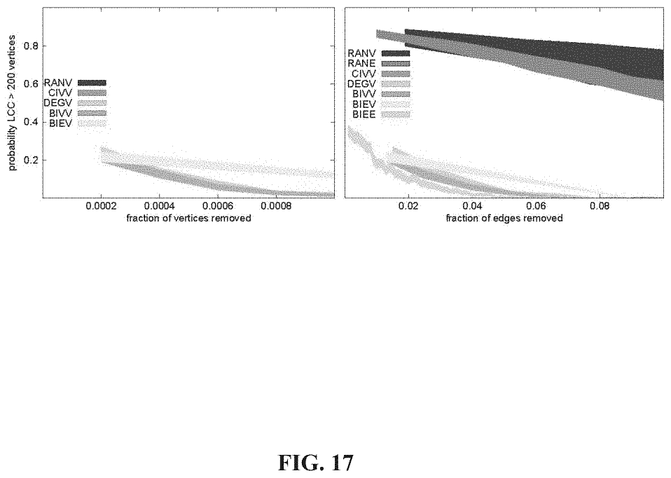

Reliability Monte Carlo estimates of the LCC₈₀₀ and LCC₄₀₀ reliabilities for the SF network at x=0.075 as top-ranked vertices or edges are removed are shown in FIG. 15; of the LCC₄₀₀ and LCC₂₀₀ reliabilities for the SF network at x=0.19, in FIG. 16; and of LCC₂₀₀ reliability for the SF+PLP network at x=0.19, in FIG. 17.

Edge Removal

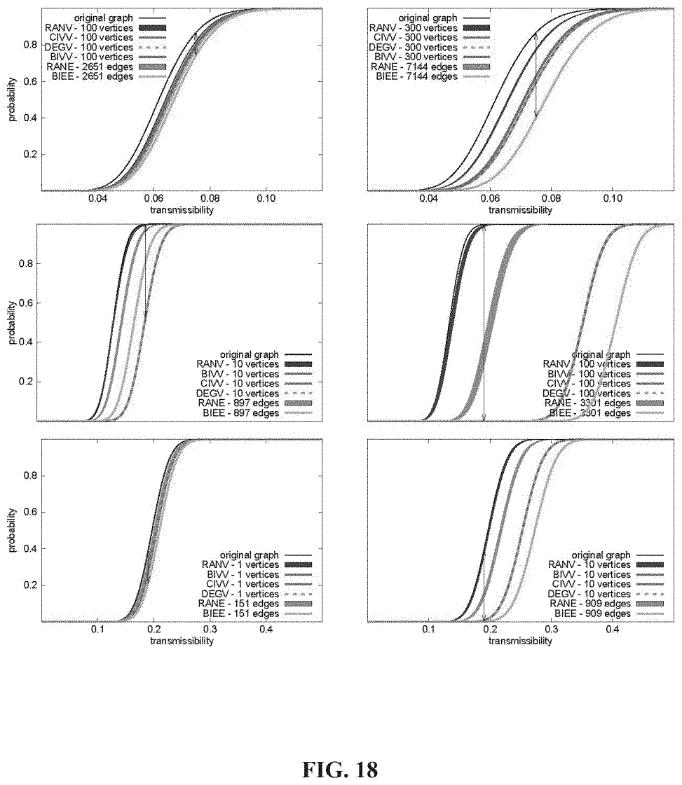

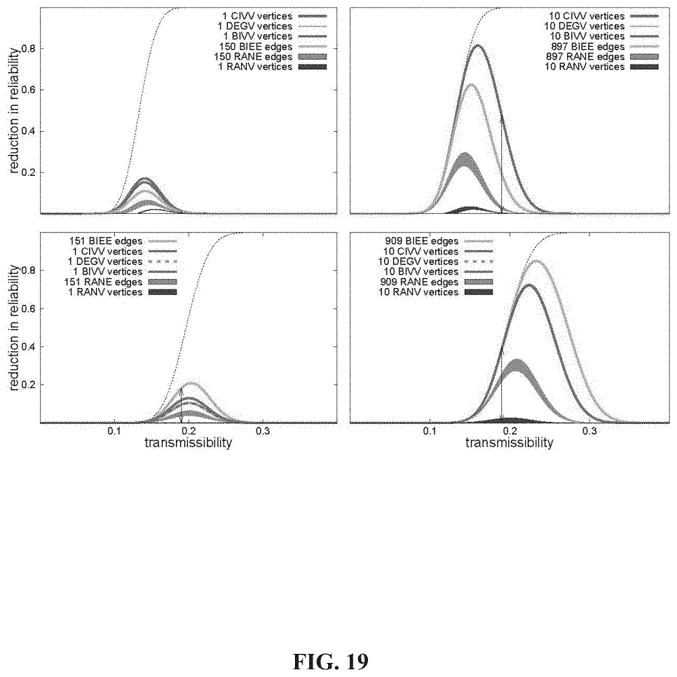

The Birnbaum importance and reduction in Birnbaum importance as vertices or edges are removed from the SF and SF+PLP networks are shown in FIGS. 18 and 19.

Comparison to Static, Local Statistics

On a graph with constrained degree distribution that is otherwise random, two closely related control parameters for the size of the LCC in SIR dynamics have been suggested:

$$1. {ϕ}_{c} ≡ \frac{〈 d 〉}{〈 {d}^{2} 〉 - 〈 d 〉} = {[ \frac{〈 {d}^{2} 〉}{〈 d 〉} - 1 ]}^{- 1}$$

from Newman's generating function analysis; (39) and

$$2. {β}_{eff} ≡ 〈 d 〉 + {σ}^{2} / 〈 d 〉 = \frac{〈 {d}^{2} 〉}{〈 d 〉} ,$$

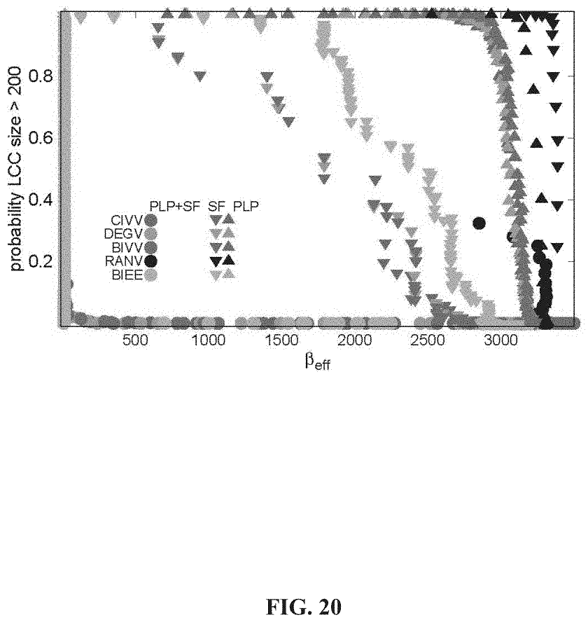

from Gao et al.'s universality analysis (36)
where (d) is the mean vertex degree. FIG. 20 illustrates the relationship between the size of the LCC and (d²)/(d) as edges and vertices are removed for both the PLP and SF networks. Notice that, while there is a strong correlation between size of the LCC and β_{eff}; the curves do not collapse onto a “universal” curve, nor does the critical point seem to be the same for both networks. Of course, the PLP network is highly structured, i.e., not at all random, and as network elements are removed by iterative optimization, both networks are driven further away from randomness. Nevertheless, this result emphasizes the danger in assuming that the degree distribution carries all the information needed to understand SIR processes on networks, especially when higher-order structure may not be random.

Features of the LCC₂₀₀ Clusters

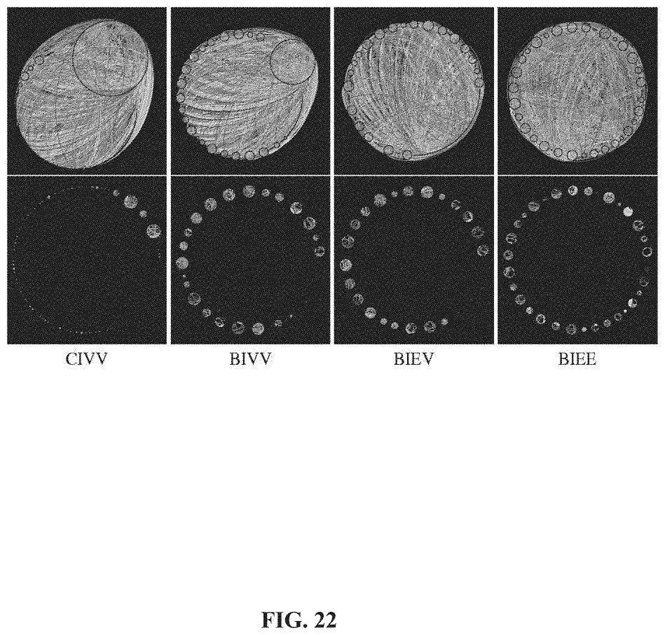

FIGS. 21-23 contrast the LCC₂₀₀ clusters in the SF, SF+PLP, and PIP networks found by the CIVV, BIVV, and BIEE methods. In general, the edge cuts found by BIEE, as would be expected, leave more of the original structure of the graph intact. Because the criterion demands only that the remaining clusters contain fewer than 201 vertices, the clusters found by BIEE are more uniform in size. For the SF+PLP and PLP networks, which were both designed to have 25 communities of 200 vertices each, a decomposition into uniformly sized clusters is a more natural solution. In these cases, the clusters found by BIEE form a useful basis for analyzing the entire network's structure, as is evident in the top right panel of FIG. 22. The CIVV method, as noted above, tends to isolate individual high-degree vertices first, which creates clusterings that have many low-degree vertices and a few near the size limit. This may be a more natural solution for scale free networks with no additional structure, but it is not as compelling for the SF+PLP and PLP networks.

Embodiments disclosed herein provide for a system, method and computer readable medium for, among other things, sensitivity of dynamical systems to interaction network topology: a statistical physical approach.

Although example embodiments of the present disclosure are explained in some instances in detail herein, it is to be understood that other embodiments are contemplated. Accordingly, it is not intended that the present disclosure be limited in its scope to the details of construction and arrangement of components set forth in the following description or illustrated in the drawings. The present disclosure is capable of other embodiments and of being practiced or carried out in various ways.

It should be appreciated that any of the components or modules referred to with regards to any of the present invention embodiments discussed herein, may be integrally or separately formed with one another. Further, redundant functions or structures of the components or modules may be implemented. Moreover, the various components may be communicated locally and/or remotely with any user/operator/customer/client or machine/system/computer/processor. Moreover, the various components may be in communication via wireless and/or hardwire or other desirable and available communication means, systems and hardware. Moreover, various components and modules may be substituted with other modules or components that provide similar functions.

It should be appreciated that the device and related components discussed herein may take on all shapes along the entire continual geometric spectrum of manipulation of x, y and z planes to provide and meet the environmental, anatomical, and structural demands and operational requirements. Moreover, locations and alignments of the various components may vary as desired or required.

It should be appreciated that various sizes, dimensions, contours, rigidity, shapes, flexibility and materials of any of the components or portions of components in the various embodiments discussed throughout may be varied and utilized as desired or required.

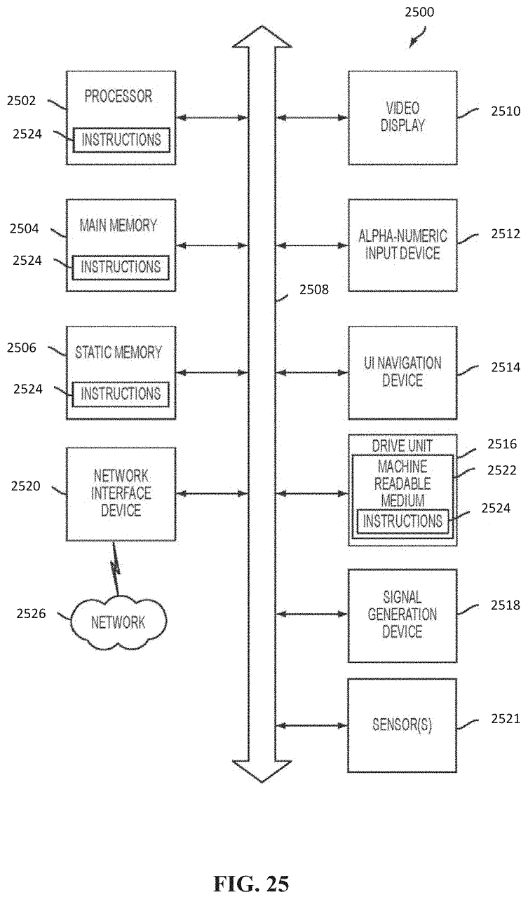

FIG. 25 is a block diagram illustrating an example of a machine upon which one or more aspects of embodiments of the present invention can be implemented. For instance, a system, method, and/or computer readable medium can be configured to provide sensitivity of dynamical systems to interaction network topology. Such an exemplary system is illustrated in a block diagram as an example machine 2500 upon which one or more embodiments (e.g., discussed methodologies) can be implemented (e.g., run).

Examples of machine 2500 can include logic, one or more components, circuits (e.g., modules), or mechanisms. Circuits are tangible entities configured to perform certain operations. In an example, circuits can be arranged (e.g., internally or with respect to external entities such as other circuits) in a specified manner. In an example, one or more computer systems (e.g., a standalone, client or server computer system) or one or more hardware processors (processors) can be configured by software (e.g., instructions, an application portion, or an application) as a circuit that operates to perform certain operations as described herein. In an example, the software can reside (1) on a non-transitory machine readable medium or (2) in a transmission signal. In an example, the software, when executed by the underlying hardware of the circuit, causes the circuit to perform the certain operations.

In an example, a circuit can be implemented mechanically or electronically. For example, a circuit can comprise dedicated circuitry or logic that is specifically configured to perform one or more techniques such as discussed above, such as including a special-purpose processor, a field programmable gate array (FPGA) or an application-specific integrated circuit (ASIC). In an example, a circuit can comprise programmable logic (e.g., circuitry, as encompassed within a general-purpose processor or other programmable processor) that can be temporarily configured (e.g., by software) to perform the certain operations. It will be appreciated that the decision to implement a circuit mechanically (e.g., in dedicated and permanently configured circuitry), or in temporarily configured circuitry (e.g., configured by software) can be driven by cost and time considerations.

Accordingly, the term “circuit” is understood to encompass a tangible entity, be that an entity that is physically constructed, permanently configured (e.g., hardwired), or temporarily (e.g., transitorily) configured (e.g., programmed) to operate in a specified manner or to perform specified operations. In an example, given a plurality of temporarily configured circuits, each of the circuits need not be configured or instantiated at any one instance in time. For example, where the circuits comprise a general-purpose processor configured via software, the general-purpose processor can be configured as respective different circuits at different times. Software can accordingly configure a processor, for example, to constitute a particular circuit at one instance of time and to constitute a different circuit at a different instance of time.

In an example, circuits can provide information to, and receive information from, other circuits. In this example, the circuits can be regarded as being communicatively coupled to one or more other circuits. Where multiple of such circuits exist contemporaneously, communications can be achieved through signal transmission (e.g., over appropriate circuits and buses) that connect the circuits. In embodiments in which multiple circuits are configured or instantiated at different times, communications between such circuits can be achieved, for example, through the storage and retrieval of information in memory structures to which the multiple circuits have access. For example, one circuit can perform an operation and store the output of that operation in a memory device to which it is communicatively coupled. A further circuit can then, at a later time, access the memory device to retrieve and process the stored output. In an example, circuits can be configured to initiate or receive communications with input or output devices and can operate on a resource (e.g., a collection of information).

The various operations of method examples described herein can be performed, at least partially, by one or more processors that are temporarily configured (e.g., by software) or permanently configured to perform the relevant operations. Whether temporarily or permanently configured, such processors can constitute processor-implemented circuits that operate to perform one or more operations or functions. In an example, the circuits referred to herein can comprise processor-implemented circuits.

Similarly, the methods described herein can be at least partially processor-implemented. For example, at least some of the operations of a method can be performed by one or processors or processor-implemented circuits. The performance of certain of the operations can be distributed among the one or more processors, not only residing within a single machine, but deployed across a number of machines. In an example, the processor or processors can be located in a single location (e.g., within a home environment, an office environment or as a server farm), while in other examples the processors can be distributed across a number of locations.

The one or more processors can also operate to support performance of the relevant operations in a “cloud computing” environment or as a “software as a service” (SaaS). For example, at least some of the operations can be performed by a group of computers (as examples of machines including processors), with these operations being accessible via a network (e.g., the Internet) and via one or more appropriate interfaces (e.g., Application Program Interfaces (APIs).)

Example embodiments (e.g., apparatus, systems, or methods) can be implemented in digital electronic circuitry, in computer hardware, in firmware, in software, or in any combination thereof. Example embodiments can be implemented using a computer program product (e.g., a computer program, tangibly embodied in an information carrier or in a machine readable medium, for execution by, or to control the operation of, data processing apparatus such as a programmable processor, a computer, or multiple computers).

A computer program can be written in any form of programming language, including compiled or interpreted languages, and it can be deployed in any form, including as a stand-alone program or as a software module, subroutine, or other unit suitable for use in a computing environment. A computer program can be deployed to be executed on one computer or on multiple computers at one site or distributed across multiple sites and interconnected by a communication network.

In an example, operations can be performed by one or more programmable processors executing a computer program to perform functions by operating on input data and generating output. Examples of method operations can also be performed by, and example apparatus can be implemented as, special purpose logic circuitry (e.g., a field programmable gate array (FPGA) or an application-specific integrated circuit (ASIC)).

The computing system can include clients and servers. A client and server are generally remote from each other and generally interact through a communication network. The relationship of client and server arises by virtue of computer programs running on the respective computers and having a client-server relationship to each other. In embodiments deploying a programmable computing system, it will be appreciated that both hardware and software architectures require consideration. Specifically, it will be appreciated that the choice of whether to implement certain functionality in permanently configured hardware (e.g., an ASIC), in temporarily configured hardware (e.g., a combination of software and a programmable processor), or a combination of permanently and temporarily configured hardware can be a design choice. Below are set out hardware (e.g., machine 2500) and software architectures that can be deployed in example embodiments.

In an example, the machine 2500 can operate as a standalone device or the machine 2500 can be connected (e.g., networked) to other machines.

In a networked deployment, the machine 2500 can operate in the capacity of either a server or a client machine in server-client network environments. In an example, machine 2500 can act as a peer machine in peer-to-peer (or other distributed) network environments. The machine 2500 can be a personal computer (PC), a tablet PC, a set-top box (STB), a Personal Digital Assistant (PDA), a mobile telephone, a web appliance, a network router, switch or bridge, or any machine capable of executing instructions (sequential or otherwise) specifying actions to be taken (e.g., performed) by the machine 2500. Further, while only a single machine 2500 is illustrated, the term “machine” shall also be taken to include any collection of machines that individually or jointly execute a set (or multiple sets) of instructions to perform any one or more of the methodologies discussed herein.

Example machine (e.g., computer system) 2500 can include a processor 2502 (e.g., a central processing unit (CPU), a graphics processing unit (GPU) or both), a main memory 2504 and a static memory 2506, some or all of which can communicate with each other via a bus 2508. The machine 2500 can further include a display unit 2510, an alphanumeric input device 2512 (e.g., a keyboard), and a user interface (UI) navigation device (e.g., a mouse). In an example, the display unit 2510, input device and UI navigation device 2514 can be a touch screen display. The machine 2500 can additionally include a storage device (e.g., drive unit) 2516, a signal generation device 2518 (e.g., a speaker), a network interface device 2520, and one or more sensors 2521, such as a global positioning system (GPS) sensor, compass, accelerometer, or other sensor.

The storage device 2516 can include a machine readable medium 2522 on which is stored one or more sets of data structures or instructions 2524 (e.g., software) embodying or utilized by any one or more of the methodologies or functions described herein. The instructions 2524 can also reside, completely or at least partially, within the main memory 2504, within static memory 2506, or within the processor 2502 during execution thereof by the machine 2500. In an example, one or any combination of the processor 2502, the main memory 2504, the static memory 2506, or the storage device 2516 can constitute machine readable media.

While the machine readable medium 2522 is illustrated as a single medium, the term “machine readable medium” can include a single medium or multiple media (e.g., a centralized or distributed database, and/or associated caches and servers) that configured to store the one or more instructions 2524. The term “machine readable medium” can also be taken to include any tangible medium that is capable of storing, encoding, or carrying instructions for execution by the machine and that cause the machine to perform any one or more of the methodologies of the present disclosure or that is capable of storing, encoding or carrying data structures utilized by or associated with such instructions. The term “machine readable medium” can accordingly be taken to include, but not be limited to, solid-state memories, and optical and magnetic media. Specific examples of machine readable media can include non-volatile memory, including, by way of example, semiconductor memory devices (e.g., Electrically Programmable Read-Only Memory (EPROM), Electrically Erasable Programmable Read-Only Memory (EEPROM)) and flash memory devices; magnetic disks such as internal hard disks and removable disks; magneto-optical disks; and CD-ROM and DVD-ROM disks.

The instructions 2524 can further be transmitted or received over a communications network 2526 using a transmission medium via the network interface device 2520 utilizing any one of a number of transfer protocols (e.g., frame relay, IP, TCP, UDP, HTTP, etc.). Example communication networks can include a local area network (LAN), a wide area network (WAN), a packet data network (e.g., the Internet), mobile telephone networks (e.g., cellular networks), Plain Old Telephone (POTS) networks, and wireless data networks (e.g., IEEE 802.11 standards family known as Wi-Fi®, IEEE 802.16 standards family known as WiMax®), peer-to-peer (P2P) networks, among others. The term “transmission medium” shall be taken to include any intangible medium that is capable of storing, encoding or carrying instructions for execution by the machine, and includes digital or analog communications signals or other intangible medium to facilitate communication of such software.

### EXAMPLES

Problem: Given a system of interacting entities, identify the contribution of a subset of the entities or interactions to the system's ability to perform a particular task.

Benefits of the disclosed methods:
1. Methods for approximate solution with bounded, controllable error.
2. Methodology weaves together dependence on network structure and dynamical parameters.
3. Methodology can distinguish very small relative differences in contributions.

Example Applications:
VLSI design
   Entities—“crummy” [Moore and Shannon, 1957] electrical components, with high probability of failure
   Interaction—logic gates, data storage, etc.
   Task—computation
   Solution provides ranked list of critical components and overall probability of completing task
Epidemic control
   Entities—people
   Interaction—contact sufficient to transmit disease
   Task—reduce the probability that disease will spread to as many as N people as much as possible.
   Solution identifies vaccination or social distancing targets that optimally reduce spread.
Communication systems
   Entities—radios
   Interaction—transmission in a noisy environment
   Task—transmit a message from a given source or sources to one or more given targets
   Solution identifies the best set of radios to upgrade within a specific budget to maximize the probability of successful transmission.

### Example 1

The example is for a simple communication system. With minor changes in interpretation it could also be an example for epidemic control or VLSI design. It is the simplest example that can illustrate both claims and why they represent improvements over the state of the art.

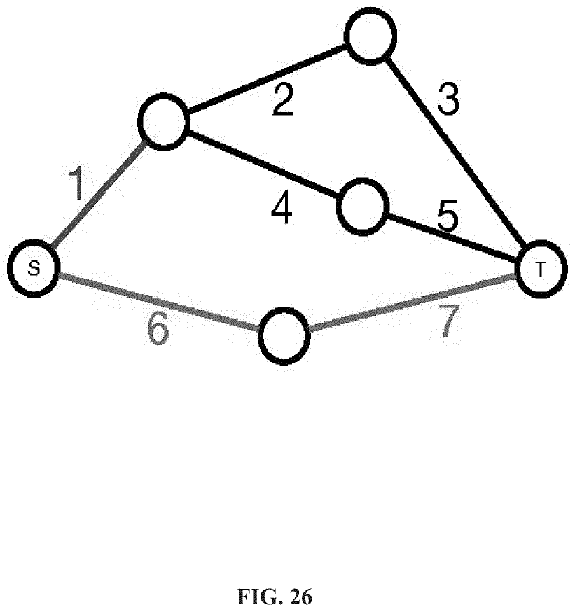

Consider a network of six radios represented by the vertices (open circles) in the graph in FIG. 26. Suppose each radio can communicate only with radios to which it is connected by one of the communication channels shown as edges 1-7 in FIG. 26. Furthermore, suppose that the communication occurs over noisy channels, so that a message sent from one radio directly to another only arrives with probability x. The “dynamical parameter” in this example is x; the “network structure” is the entire list of edges.

It is desired to send a message reliably from the radio marked S to the one marked with T. There is a budget for improving the performance of one channel. The question is which one should be improved?

By the symmetry in this particular network, it is evident that the channels can be grouped into three categories, indicated by colors in FIG. 26. It is also evident that the single most important channel is either edge 1 or one of the edges 6 or 7. (This analysis is not part of the methods, but serves to simplify the following discussion.) The disclosed method is used to provide estimates for the contribution either edge 1 or edge 6 makes to the probability of successful transmission from S to T.

Application of the disclosed method to this example involves the following steps:

1. Construct a Taylor series expansion for R₁(x)−R₆(x) at x=0 using struts.
(a) Identify (or randomly sample, for a larger graph) m minimal struts.
(b) (For benefits 1 and 2) Construct all possible combinations of up to H of the subsets of minimal struts.
(c) (For benefits 1 and 2) For each combination, add a term to the Taylor series Rₛ.
(d) (For benefit 3) Construct all possible combinations of up to H of the subsets of minimal struts that include either edge 1 or edge 6, but not both.
(e) (For benefit 3) For each combination add a term to the Taylor series Dₛ.

2. Construct a Taylor series expansion for R₁(x)−R₆(x) at x=1 using cuts.
(a) Identify (or randomly sample, for a larger graph) m′ minimal cuts.
(b) (For benefits 1 and 2) Construct all possible combinations of up to H of the m′ minimal cuts.
(c) (For benefits 1 and 2) For each combination, add a term to the Taylor series T_{c}.
(d) (For benefit 3) Construct all possible combinations of up to H of the m′ minimal cuts that include either edge 1 or edge 6, but not both.
(e) (For benefit 3) For each combination add a term to the Taylor series D_{c}.

3. Construct a Bezier polynomial that combines the information in the Taylor series T_{c} and Tₛ.

4. Construct a Bezier polynomial that combines the information in the Taylor series D_{c} and Dₛ.

The resulting Bezier polynomial must have N=7 coefficients; the combined Taylor series will determine the first k(H) and the last k(H) of them. If k(H)−k(H)<N, it is possible to insert upper and lower bounds for the undetermined coefficients to create upper and lower bounds for the estimate. To increase k(H) and k(H), the number of combinations H considered and/or the number m and m′ of samples drawn must be increased. The time required to increase H is roughly exponential in H (strictly speaking, (^{m}_{H})). The time required to draw more samples depends on the network and the task.

Exact Analysis

This simple system can be analyzed exactly, with the result that:

R(x)=x²+2x³−3x⁵+x⁷. (53)

This is also the Taylor series for R at x=0. The Taylor series for R at x=1 is

R(y)=1−2y²−7y³+20y⁴−18y⁵+7y⁶−y⁷, where y=1−x. (54)

Equivalently, the Taylor coefficients are:

\vec{α}=(0,0,1,2,0,−3,0,−1) (55)

\overline{\vec{α}}=(1,0,−2,−7,20,−18,7,−1). (56)

The Bernstein coefficients are:

$$\begin{matrix}{β}^{->} = ( 0 , 0 , \frac{1}{21} , \frac{1}{5} , \frac{18}{35} , \frac{19}{21} , 1 , 1 ) & ( 57 ) \\ {\overline{β}}^{->} = ( 1 , 1 , \frac{19}{21} , \frac{18}{35} , \frac{1}{5} , \frac{1}{21} , 0 , 0 ) . & ( 58 )\end{matrix}$$

Notice that, although the Taylor coefficients are not related in any obvious way, the Bernstein coefficients satisfy βₖ=β̅_{N-k}.

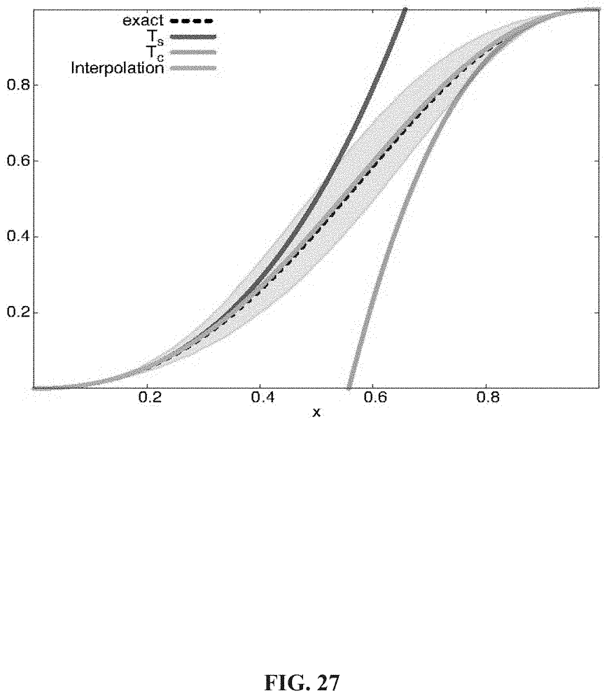

These functions are plotted in FIG. 27. Notice that the dependence on x is not trivial. In particular, the relative importance of the two edges changes when 1−2x+x³=0, at around x=0.618. That is, the best communication channel to improve depends bot on the network structure and the dynamical parameter. For this network, when x<0.618, edge 1 is more important than edge 6, and vice versa for x>0.618.

Similarly, the relative importance of edges 1 and 6 is given by

D(x)=x²−2x³+x⁵ (59)

D(y)=−y+5y²−8y³+5y⁴−y⁵, where y=1−x (60)

with Taylor coefficients

\vec{γ}=(0,0,1,−2,0,1) (61)

\overline{\vec{γ}}=(0,−1,5,−8,5,−1) (62)

and Bernstein coefficients

\vec{γ}=(0,0,1,−2,0,1) (63)

\overline{\vec{γ}}=(0,−1,5,−8,5,−1) (64)

which also satisfy δ=δ̅_{N-k}.

Approximation Using the Disclosed Method

1. Construct a Taylor series expansion for R₁(x)−R₆(x) at x=0 using minimal struts.
(a) Identify (or randomly sample, for a larger graph) m minimal struts. There are three minimal struts for this example network, specifically, the sets of edges:

{1,2,3},{1,4,5},{6,7}. (65)
(b) (For benefits 1 and 2) Construct all possible combinations of up to H of the subsets of minimal struts. There are seven possible non-empty combinations of the three minimal struts:

H=1: {1,2,3},{1,4,5},{6,7} (66)

H=2: {1,2,3,4,5},{1,2,3,6,7},{1,4,5,6,7} (67)

H=3: {1,2,3,4,5,6,7}. (68)
(c) (For benefits 1 and 2) For each combination, add a term to the Taylor series Tₛ. For H=1 there are three “combinations” of exactly 1 of the minimal struts, 1 of size 2 and 2 of size 3, yielding: Tₛ(x)=x²+2x³.
(d) (For benefit 3) Construct all possible combinations of up to H of the subsets of minimal struts that include either edge 1 or edge 6, but not both. There is only one combination of minimal struts at any depth H that includes edge 6 but not edge 1: {6, 7}. There are three combinations that include edge 1 but not edge 6: (1, 2, 3), (1, 4, 5), (1, 2, 3, 4, 5). The first two of these will be included at depth H=1, the third only at H=2.
(e) For each combination, add a term to the Taylor series D, corresponding to its size, whose sign depends on whether it is the union of an even number of minimal struts and whether it includes edge 6 or edge 1. The combinations above give Dₛ=x²−2x³+x⁵.

2. Construct a Taylor series expansion for R₁(x)−R₆(x) at x=−1l using minimal cuts.
(a) Identify (or randomly sample, for a larger graph) m′ minimal cuts. The sets of edges in the 10 minimal cuts are shown in Table 3.

TABLE 3
The ten minimal cuts in the example network.

| | | | | |
|---|---|---|---|---|
| {1, 6} | {2, 4, 6} | {2, 5, 6} | {3, 4, 6} | {3, 5, 6} |
| {1, 7} | {2, 4, 7} | {2, 5, 7} | {3, 4, 7} | {3, 5, 7} |

(b) Construct all possible combinations of up to H of the m′ minimal cuts. For H=1 each of the ten entries in Table 3 is a possible combination. There are 2 entries of size 2 and 8 entries of size 3. However, examining the combinations that include 2 minimal cuts, it can be seen that there is one, {1, 6, 7}, that includes only three edges. Hence, the Taylor coefficient for y³ is not determined exactly at H=1, and it can be ignored.
(c) For each combination, add a term to the Taylor series T_{c}. For H=1, the cuts in Table 3 give T_{c}(y)=2y², ignoring the term in y³.
(d) Construct all possible combinations of up to H of the m′ minimal cuts that include either edge 1 or edge 6, but not both. For H=1 there are five minimal cuts that include either edge 1 or edge 6, but not both—those in the bottom row of the table.
(e) For each combination, add a term to the Taylor series D_{c}. For H=1, the cuts in the Table give D_{c}(y)=y²−4y³.

3. Construct a Bezier polynomial that combines the information in T_{c} and Tₛ. At H=1 for both struts and cuts, the two Taylor series are:

Tₛ(x)=x²+2x³ (69)

T_{c}(y)=2y². (70)

The coefficients can be represented as vectors, where “?” indicates an unknown coefficient. These could be evaluated by using larger values of H.

\vec{α}=(0,0,1,2,?,?,?,?) (71)

\overline{\vec{α}}=(0,0,2,?,?,?,?,?). (72)

The Bezier coefficients are determined using the transformation

$${β}_{k} = {\sum }_{j = 0}^{k} {T}_{kj} {α}_{j} , \\ where {T}_{k , j} ≡ ( \begin{matrix}k \\ j\end{matrix} ) / ( \begin{matrix}N \\ j\end{matrix} ) = ( \begin{matrix}N - j \\ k - j\end{matrix} ) / ( \begin{matrix}N \\ k\end{matrix} ) . \qquad ( 73 )$$

For this example, N=7, yielding:

\vec{β}=(0,0, 1/21, 3/35,?,?,?,?) (74)

\overline{\vec{α}}=(0,0, 2/21,?,?,?,?,?). (75)

Assembling these using the property that βₖ=β̅_{N-k} determines all but one of the coefficients:

\vec{β}=(0,0, 1/21, 3/35,?,2/21,0,0). (76)

The missing coefficient must lie between its neighbors, i.e., 0.0857≈ 3/35≤?≤ 2/21≈0.0952. These are the bounds mentioned in benefit 1. FIG. 27 compares the exact solution, both Taylor series, the bounds on approximation, and a simple approximation constructed by linear interpolation of the missing coefficient(s).

4. Construct a Bezier polynomial that combines the information in D_{c} and Dₛ. At H=1 for both struts and cuts, the two Taylor series are:

Dₛ(x)=x²−2x³ (77)

D_{c}(y)=y²−4y³. (78)

The coefficients can be represented as vectors

\vec{γ}=(0,0,1,−2,?,?,?,?) (79)

\overline{\vec{γ}}=(0,0,1,−4,?,?,?,?). (80)

yielding:

\vec{δ}=(0,0, 1/10, 1/10,?,?,?) (81)

\overline{\vec{δ}}=(0,0, 1/10, 1/10,?,?,?) (81)

Assembling these completely determines all the coefficients:

\overline{\vec{δ}}=(0,0, 1/10, 1/10,−⅕,0). (83)

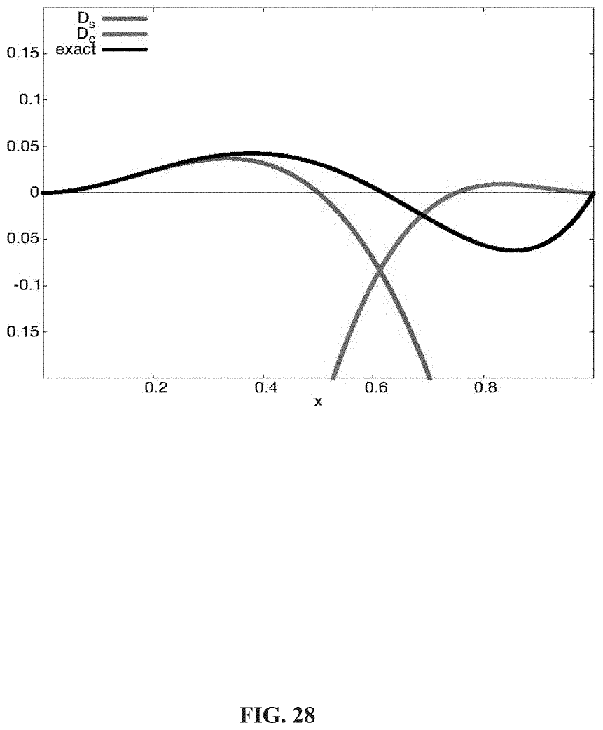

This gives the exact answer, which is compared with the approximations Dₛ and D_{c} in FIG. 28.

The restriction to the set of minimal cuts that include either edge 1 or edge 6 but not both improves the estimation of their relative importance, allowing for the detection of very small relative differences in contributions, as asserted in benefit 3.

FIG. 28 compares the exact solution to the Taylor series. In this example, the approximate solution is in fact exact, and we can tell this is true with our approximation methodology.

It should be appreciated that while some dimensions are provided on the aforementioned figures, the device may constitute various sizes, dimensions, contours, rigidity, shapes, flexibility and materials as it pertains to the components or portions of components of the device, and therefore may be varied and utilized as desired or required.

It must also be noted that, as used in the specification and the appended claims, the singular forms “a,” “an” and “the” include plural referents unless the context clearly dictates otherwise. Ranges may be expressed herein as from “about” or “approximately” one particular value and/or to “about” or “approximately” another particular value. When such a range is expressed, other exemplary embodiments include from the one particular value and/or to the other particular value.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

Some references, which may include various patents, patent applications, and publications, are cited in a reference list and discussed in the disclosure provided herein. The citation and/or discussion of such references is provided merely to clarify the description of the present disclosure and is not an admission that any such reference is “prior art” to any aspects of the present disclosure described herein. In terms of notation, “[n]” corresponds to the n^{th} reference in the list. All references cited and discussed in this specification are incorporated herein by reference in their entireties and to the same extent as if each reference was individually incorporated by reference.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g. 1 to 5 includes 1, 1.5, 2, 2.75, 3, 3.90, 4, 4.24, and 5). Similarly, numerical ranges recited herein by endpoints include subranges subsumed within that range (e.g. 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

In summary, while the present invention has been described with respect to specific embodiments, many modifications, variations, alterations, substitutions, and equivalents will be apparent to those skilled in the art. The present invention is not to be limited in scope by the specific embodiment described herein. Indeed, various modifications of the present invention, in addition to those described herein, will be apparent to those of skill in the art from the foregoing description and accompanying drawings. Accordingly, the invention is to be considered as limited only by the spirit and scope of the disclosure (and claims) including all modifications and equivalents.

Still other embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of this application. For example, regardless of the content of any portion (e.g., title, field, background, summary, abstract, drawing figure, etc.) of this application, unless clearly specified to the contrary, there is no requirement for the inclusion in any claim herein or of any application claiming priority hereto of any particular described or illustrated activity or element, any particular sequence of such activities, or any particular interrelationship of such elements. Moreover, any activity can be repeated, any activity can be performed by multiple entities, and/or any element can be duplicated. Further, any activity or element can be excluded, the sequence of activities can vary, and/or the interrelationship of elements can vary. Unless clearly specified to the contrary, there is no requirement for any particular described or illustrated activity or element, any particular sequence or such activities, any particular size, speed, material, dimension or frequency, or any particularly interrelationship of such elements. Accordingly, the descriptions and drawings are to be regarded as illustrative in nature, and not as restrictive. Moreover, when any number or range is described herein, unless clearly stated otherwise, that number or range is approximate. When any range is described herein, unless clearly stated otherwise, that range includes all values therein and all sub ranges therein. Any information in any material (e.g., a United States/foreign patent, United States/foreign patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such incorporated by reference material is specifically not incorporated by reference herein.

### REFERENCES

The following patents, applications and publications as listed below and throughout this document are hereby incorporated by reference in their entirety herein.
1. P. Grassberger, On the critical behavior of the general epidemic process and dynamical percolation, Mathematical Biosciences pp. 157-172 (1983).
2. R. Albert, H. Jeong, A.-L. Barabási, Error and attack tolerance of complex networks, Nature 406, 378 (2000).
3. D. S. Callaway, M. E. Newman, S. H. Strogatz, D. J. Watts, Network robustness and fragility: Percolation on random graphs, Physical Review Letters 85, 5468 (2000).
4. R. Cohen, K. Erez, D. Ben-Avraham, S. Havlin, Resilience of the internet to random breakdowns, Physical Review Letters 85, 4626 (2000).
5. F. Morone, H. A. Makse, Influence maximization in complex networks through optimal percolation, Nature 524, 65 (2015).
6. A. Bavelas, Communication patterns in task-oriented groups, Journal of the Acoustical Society of America 22, 725 (1950).
7. A. Ganesh, L. Massoulié, D. Towsley, The effect of network topology on the spread of epidemics, Proceedings of the IEEE 24th Annual Joint Conference of the IEEE Computer and Communications Societies Miami, Fla. 2, 1455 (2005).
8. D. Kempe, J. Kleinberg, É. Tardos, Proceedings of the Ninth ACM SIGKDD International Conference on Knowledge Discovery and Data Mining (ACM, 2003), pp. 137-146.
9. L. C. Freeman, A set of measures of centrality based on betweenness, Sociometry pp. 35-41 (1977).
10. M. E. J. Newman, Modularity and community structure in networks, Proceedings of the National Academy of Sciences 103, 8577 (2006).
11. R. Estes, E. Lancaster, Two-point Taylor series expansions, Tech. Rep. TMX-55759, NASA (1966).
12. Y. Ren, S. Eubank. M. Nath, From network reliability to the Ising model: A parallel scheme for estimating the joint density of states. Physical Review E 94, 042125 (2016).
13. M. Nath, Application of network reliability to analyze diffusive processes on graph dynamical systems, Ph.D. thesis, Virginia Tech (2019).
14. M. Youssef, Y. Khorramzadeh, S. Eubank, Network reliability: the effect of local network structure on diffusive processes, Physical Review E 88, 052810 (2013).
15. S. Eubank, M. Youssef, Y. Khorramzadeh, 2013 International Conference on Signal-Image Technology & Internet-Based Systems (SITIS) (IEEE, 2013), pp. 641-648.
16. Y. Khorramzadeh, M. Youssef, S. Eubank, S. Mowlaei, Analyzing network reliability using structural motifs, Physical Review E 91, 042814 (2015).
17. E. Moore, C. Shannon, Reliable circuits using less reliable relays, Journal of the Franklin Institute 262, 191 (1956).
18. C. J. Colbourn, The Combinatorics of Network Reliability (Oxford University Press, 1987).
19. M. V. Lomonosov, V. P. Polesskii, An upper bound for the reliability of information networks, Problemy Peredac̆i Informacii 7, 78 (1971).
20. V. Polesskii, Untying of clutter-family supports and its role in the monotone-structure reliability theory, Problems of Information Transmission 37, 140 (2001).
21. D. S. Johnson, Proceedings of the fifth annual ACM Symposium on the Theory of Computing (ACM, 1973), pp. 38-49.
22. M. Yannakakis, On the approximation of maximum satisfiability, Journal of Algorithms 17, 475 (1994).
23. L. Ford, D. Fulkerson, Maximal flow through a network, Canadian Journal of Mathematics 8, 399 (1956).
24. G. G. Lorentz, Bernstein polynomials (American Mathematical Soc., 2013).
25. R. T. Farouki, The Bernstein polynomial basis: A centennial retrospective, Computer Aided Geometric Design 29, 379 (2012).
26. Z. W. Birnbaum, Multivariate Analysis—II, Proceedings of the 2nd International Symposium on Multivariate Analysis, P. R. Krishnaiah, ed. (Academic Press, New York, 1969), pp. 581-592.
27. L. Page, J. Perry, Reliability polynomials and link importance in networks, IEEE Transactions on Reliability pp. 51-58 (1994).
28. I. Gertsbakh, Y. Shpungin, Models of Network Reliability: Analysis, Combinatorics, and Monte Carlo (Taylor & Francis, 2009).
29. G. L. Nemhauser, L. A. Wolsey, M. L. Fisher, An analysis of approximations for maximizing submodular set functions I, Mathematical Programming 14, 265 (1978).
30. D. Centola, M. Macy, Complex contagions and the weakness of long ties, American Journal of Sociology 113, 702 (2007).
31. M. Granovetter, Threshold models of collective behavior, American Journal of Sociology 83, 1420 (1978).
32. T. C. Schelling, Micromotives and Macrobehavior (W. W. Norton & Company, 2006).
33. G. Kirchhoff, Über die auflösung der gleichungen, auf welche man bei der untersuchung der linearen verteilung galvanischer stro\ddot{ } me gefuhrt wird, Ann. Phys. Chem. 72, 497 (1847).
34. F. Harary, Graph Theory (Addison-Wesley, Reading, Mass., 1969).
35. L. Ford, D. Fulkerson, Flows in Networks (Princeton University Press, 1962).
36. J. Gao, B. Barzel, A.-L. Barabási, Universal resilience patterns in complex networks, Nature 530, 307 (2016).
37. P. W. Holland, K. B. Laskey, S. Leinhardt, Stochastic blockmodels: First steps, Social networks 5, 109 (1983).
38. B. Karrer, M. E. Newman, Stochastic blockmodels and community structure in networks, Physical review E 83, 016107 (2011).
39. M. E. J. Newman, Networks: an Introduction (Oxford University Press, 2010).

1. A system for determining a sensitivity of a networked system, the system comprising a processor configured to:
identify elements of a networked system, the elements including a vertex (V) that represents a constituent and a state of the constituent, and an interaction (E) between at least two Vs;
define an interaction-dependent function \vec{ω}(\vec{x}) that gives a transition probability for each E as a function of dynamical parameters \vec{x} of the networked system, wherein a V specific interaction-dependent function, ω_{i,s′}(\vec{x}; s, s₁, . . . , s_{di}), provides a probability that, when a perturbation occurs, Vi will be in state s′ given that it is currently in state s and its Vdᵢ neighbors are currently in states s₁, . . . , s_{d};
define a network reliability, R_{G,} [symbol] (\vec{w}), that represents a probability that a V's state holds when a perturbation occurs;
sample a sample size, S, and evaluate only O(S^{D}) of the possible 2^{E} terms in a Taylor series, wherein D is expansion order;
identify interpolating polynomials between the Taylor series at x=0 and x=1 that are bounded;
define a cost function that optimizes a property of the networked system for a fixed cost; and
perturb the networked system until R_{G,} [symbol] (\vec{w})=zero for a particular x to estimate a sensitivity of the networked system.

2. The system of claim 1, wherein the processor is configured to estimate monotonic properties of the networked system.

3. The system of claim 1, wherein the processor is configured to evaluate only O(S^{D}) of the possible 2^{E} terms in a Taylor series for D<<E.

4. The system of claim 1, wherein the processor is configured to use Bernstein polynomials.

5. The system of claim 5, wherein the processor is configured to approximate a continuous function ƒ(x) defined by Σdk=₀ƒ(k/d)B(d,k,x) for each Bernstein polynomial, and identify polynomials of degree N whose first k₁ derivatives at x=0 and first k₂ derivatives at x=1 match known values.

6. The system of claim 1, wherein the processor is configured to remove a V and/or an E as part of the perturbation.

7. The system of claim 6, wherein the processor is configured remove a V and/or an E iteratively.

8. The system of claim 1, wherein the processor is configured to remove all Es for a specific V or group of Vs as part of the perturbation.

9. The system of claim 1, wherein the networked system is a networked dynamical system.

10. The system of claim 1, wherein the processor is configured to prioritize changes to the networked system based on the sensitivity of the networked system.

11. The system of claim 10, wherein the changes include one or more of targeting, hardening, or upgrading the networked system.

12. A method for determining a sensitivity of a networked system, the method comprising:
identifying elements of a networked system, the elements including a vertex (V) that represents a constituent and a state of the constituent, and an interaction (E) between at least two Vs;
defining an interaction-dependent function \vec{ω}(\vec{x}) that gives a transition probability for each E as a function of dynamical parameters \vec{x} of the networked system, wherein a V specific interaction-dependent function, ω_{i,s′}(\vec{x}; s, s₁, . . . , s_{di}), provides a probability that, when a perturbation occurs, Vi will be in state s′ given that it is currently in state s and its Vdᵢ neighbors are currently in states s₁, . . . , s_{d};
defining a network reliability, R_{G,} [symbol] (\vec{w}), that represents a probability that a V's state holds when a perturbation occurs;
sampling a sample size, S, and evaluating only O(S^{D}) of the possible 2^{E} terms in a Taylor series, wherein D is expansion order;
identifying interpolating polynomials between the Taylor series at x=0 and x=1 that are bounded;
defining a cost function that optimizes a property of the networked system for a fixed cost;
perturbing the networked system until R_{G,} [symbol] (\vec{w})=zero for a particular x to estimate a sensitivity of the networked system.

13. The method of claim 12, wherein estimating of sensitivity involves estimating monotonic properties of the networked system.

14. The method of claim 12, wherein evaluating only O(S^{D}) of the possible 2^{E} terms in a Taylor series is done for D<<E.

15. The method of claim 12, wherein the polynomials are Bernstein polynomials.

16. The method of claim 15, wherein each Bernstein polynomial is an approximation of a continuous function ƒ(x) defined by Σdk=₀ƒ(k/d)B(d,k,x), and identifying interpolating polynomials involves identifying polynomials of degree N whose first k₁ derivatives at x=0 and first k₂ derivatives at x=1 match known values.

17. The method of claim 12, wherein the perturbation involves any one or combination of: removing a V and/or an E; removing a V and/or an E iteratively; or removing all Es for a specific V or group of Vs.

18. The method of claim 12, comprising:
prioritizing changes to the networked system based on the sensitivity of the networked system.

19. The method of claim 18, wherein the changes involve one or more of targeting, hardening, or upgrading the networked system.

20. A computer readable medium having instructions stored thereon, the instructions configured to cause a processor to:
identify elements of a networked system, the elements including a vertex (V) that represents a constituent and a state of the constituent, and an interaction (E) between at least two Vs;
define an interaction-dependent function \vec{ω}(\vec{x}) that gives a transition probability for each E as a function of dynamical parameters \vec{x} of the networked system, wherein a V specific interaction-dependent function, ω_{i,s′}(\vec{x}; s, s₁, . . . , s_{di}), provides a probability that, when a perturbation occurs, Vi will be in state s′ given that it is currently in state s and its Vdᵢ neighbors are currently in states s₁, . . . , s_{d};
define a network reliability, R_{G,} [symbol] (\vec{ω}), that represents a probability that a V's state holds when a perturbation occurs;
sample a sample size, S, and evaluate only O(S^{D}) of the possible 2^{E} terms in a Taylor series, wherein D is expansion order;
identify interpolating polynomials between the Taylor series at x=0 and x=1 that are bounded;
define a cost function that optimizes a property of the networked system for a fixed cost; and
perturb the networked system until R_{G,} [symbol] (\vec{w}) zero for a particular x to estimate a sensitivity of the networked system.
